(19) United States
(12) Patent Application Publication
(10) Pub. No.: US 2009/0255568 A1
(43) Pub. Date: Oct. 15, 2009

(54) SOLAR PANEL WINDOW

(75) Inventor: John Paul MORGAN, Toronto (CA)

Correspondence Address: BORDEN LADNER GERVAIS LLP;Anne Kinsman, WORLD EXCHANGE PLAZA, 100 QUEEN STREET SUITE 1100, OTTAWA, ON, K1P 1J9, CA

(73) Assignee: Morgan Solar Inc., Toronto (CA)

(21) Appl. No.: 12/417,424

(22) Filed: Apr. 2, 2009

Related U.S. Application Data
(63) Continuation-in-part of application No. 12/113,705, filed on May 1, 2008.
(60) Provisional application No. 60/915,207, filed on May 1, 2007.
(60) Provisional application No. 60/942,745, filed on Jun. 8, 2007.
(60) Provisional application No. 60/951,775, filed on Jul. 25, 2007.
(60) Provisional application No. 61/041,756, filed on Apr. 2, 2008.
(60) Provisional application No. 61/145,321, filed on Jan. 16, 2009.
(60) Provisional application No. 61/151,006, filed on Feb. 9, 2009.

(51) Int. Cl. H01L 31/052; H01L 31/042

(52) U.S. Cl. 136/246; 136/244

(57) ABSTRACT

A solar panel window for mounting to a building. The window has an interior pane and an exterior pane adjacent to each other. The exterior pane has a first ridged surface and the interior pane has a second ridged surface, which is complementary to the first ridged surface. The exterior and interior panes are secured together with their ridged surfaces facing each other. A plurality of photovoltaic solar cells are mounted on the first ridged surface of the exterior pane. The solar panel window allows light impinging thereon through a pre-determined viewing angle to be transmitted inside the building. Light impinging on the window outside the pre-determined viewing angled is directed to the plurality of solar cells.

### CROSS REFERENCE TO RELATED APPLICATIONS

The present application is a continuation in part of U.S. application Ser. No. 12/113,705 filed May 1, 2008, which claims the benefit of U.S. Provisional Patent Application No. 60/915,207 filed May 1, 2007; U.S. Provisional Patent Application No. 60/942,745 filed Jun. 8, 2007; and U.S. Provisional Patent Application No. 60/951,775 filed Jul. 25, 2007, which are incorporated herein by reference in their entirety. The present application claims the benefit of U.S. Provisional Patent Application No. 61/041,756 filed Apr. 2, 2008; U.S. Provisional Patent Application No. 61/145,321 filed Jan. 16, 2009; and U.S. Provisional Patent Application No. 61/151,006 filed Feb. 9, 2009, which are incorporated herein by reference in their entirety.

### FIELD OF THE INVENTION

The present invention relates generally to the harvesting of solar energy. More particularly, the present invention relates to a solar light-guide concentrator that can be used as a window.

### BACKGROUND OF THE INVENTION

On many buildings, the windows and walls receive a substantial amount of sunlight, which can lead to high temperatures and to bright illumination inside the building. This can lead to sub-optimal ambient conditions unless the building is air-conditioned and/or blinds are put up. However, the presence of blinds prevents natural light from coming in.

Some companies offer solar panel windows that are glazed with thin films of photovoltaic material to capture sunlight, while allowing some transparency. The downside of this approach is that direct sunlight and reflected sunlight are equally attenuated, which means that the windows become darker when viewed from any angle. That is, these windows equally attenuate direct sunlight and ambient light. These windows are not clear, but dark, like sunglasses.

Therefore, it is desirable to provide a solar panel window that can substantially harvest direct sunlight and transmit reflected sunlight without substantial attenuation of the ambient light.

### SUMMARY OF THE INVENTION

In a first aspect of the invention, there is provided an apparatus for collecting light. The apparatus comprises a light-capturing pane made of a first optically transmissive material having a first refractive index. The light-capturing pane has a planar input surface and an opposite, ridged output surface. The planar input surface is in contact with an exterior medium having an exterior medium refractive index. The ridged output surface includes a plurality of pairs of adjoining surfaces, each pair of adjoining surfaces defines a ridge. Each pair of adjoining surfaces has a reflective surface and a collector surface. The reflective surface is in contact with a second optically transmissive material having a second refractive index, which is lower than the first refractive index. The apparatus further comprises a plurality of light-collecting devices in optical communication with respective collector surfaces. The apparatus has a first critical capture angle defined in accordance with at least an orientation of the reflective surfaces with respect to the planar input surface, the exterior medium refractive index, the first refractive index and the second refractive index. A portion of light incident on the input surface at an angle of incidence at least as large as the first critical capture angle is directed to one of the reflective surfaces to undergo a first total internal reflection and, therefrom, to propagate, within the light-capturing pane, to one of the collector surfaces for harvesting by a respective light-collecting device.

The apparatus can further comprise a reflecting structure spaced-apart from the light-capturing pane. The reflecting structure faces the ridged output surface. The reflector structure and the ridged output surface define a volume therebetween. The volume is filled substantially by the second optically transmissive material. The reflector structure has a shape complementary to the ridged output surface of the light-capturing pane. The apparatus having a second critical capture angle which is such that a portion of light incident at an angle comprised between the second critical capture angle and the first critical capture angle is directed toward a reflective surface, transmits through the reflective surface and through the second optically transmissive material to reflect off a segment of the reflecting structure. The segment is substantially parallel to the reflective surface. From the segment of the reflecting structure, the light propagates through the second optically transmissive material, transmits through the reflective surface and propagate within the first optically transmissive material towards a light-collecting device. The reflecting structure can includes one of a metallic reflector, a dielectric reflector, and a reflective hologram.

The apparatus can further comprise a transmissive hologram to receive light incident thereon at a first angle and to transmit the light towards the input surface at a second angle.

The apparatus of claim 1 further comprising a light-rectifying pane made of a third optically transmissive material having a third refractive index, the light-rectifying layer having a ridged input surface complementary to the ridged output surface of the light-capturing pane, the light-rectifying pane further having a planar output surface opposite the ridged input surface, the light-rectifying pane being spaced apart from the light-capturing pane with the output ridged surface facing the input ridged surface, light being incident on the light-capturing pane at an angle of incidence less that the first critical capture angle being transmitted through the light-capturing pane, into the light-rectifying pane and exiting the light-rectifying pane through the planar output surface of the light-rectifying layer. The third refractive index can be substantially equal to the first refractive index. Each reflective surface of the light-capturing pane can have a counterpart surface in the light-rectifying pane, and each reflective surface can be substantially parallel to its counterpart surface.

The apparatus can be such that each collector surface is substantially orthogonal to the planar input surface of the light-capturing pane.

The light-capturing pane can comprise a layer of optically transmissive material that has a refractive index lower that that the first refractive index. The layer can be formed between the input surface and the ridged output surface.

The light-capturing pane can include an optically transmissive sheet and a plurality of prisms secured to the optically transmissive sheet. The prisms can include a matrix and a plurality of aggregates disposed in the matrix. The aggregates can include at least one of cylinder-shaped aggregates, parallepiped-shaped aggregates, sphere-shaped aggregates, wedge-shaped aggregates, and random-shaped aggregates.

The light-collecting devices are photovoltaic cells.

The first optically transmissive material includes at least one of glass, poly(methyl methacrylate), polycarbonate, urethane, poly-Urethane, silicone rubber, optical epoxies, and cyanoacrylates or any suitable combination thereof.

In a second aspect of the invention, the present invention provides a solar panel window that comprises a first pane and a second pane adjacent to each other. The first pane has a first ridged surface and the second pane has a second ridged surface. The first and second ridged surfaces are complementary to each other. The first and second panes are secured to each other with the first ridged surface facing the second ridged surface. The solar panel window further comprises a plurality of solar cells mounted on the first ridged surface.

The first ridged surface can include a plurality of prismatic ridges, each ridge having a long side and a short side, the plurality of solar cell being mounted to the short sides.

In a third aspect of the invention, there is provided a solar panel window that comprises a light input sheet and a light output sheet. The solar panel window further comprises a plurality of compound light capture prisms formed between the light input sheet and the light output sheet. Each compound light capture prism includes a first capture prism having a first refractive index and a second capture prism having a second refractive index. The second refractive index is greater than the first refractive index. The first capture prism and the second capture prism abut each other to define a total internal reflection interface. The second capture prism has a collector face. The first capture prism can receive light from the light input sheet and propagate the light to the second capture prism, through the total internal reflection interface. The second capture prism can propagate the light received from the first capture prism to the collector face. The solar panel window further comprises a plurality of photovoltaic cells in optical communication with respective collector faces. Each photovoltaic cell can generate a voltage in accordance with the light received at its respective collector face.

The solar panel window can allow light impinging thereon through a pre-determined viewing angle to be transmitted inside a building to which the solar panel window is mounted with light impinging on the window outside the pre-determined viewing angled being directed to the plurality of solar cells.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 shows a perspective view of an embodiment of a Capture Layer of the present disclosure;

FIGS. 2A and 2B show a side view of the Capture Layer of FIG. 1, with solar cells secured to the Capture Layer;

FIGS. 3A and 3B show the Capture Layer of FIGS. 2A and 2B with incoming rays at different angles of incidence;

FIGS. 4A-4C show the economy of photovoltaic cell material that can be realized with the Capture Layer of FIG. 1;

FIG. 5 shows how concentration of light can be realized with a prism of the Capture Layer of FIG. 1;

FIG. 6 shows how an additional solar cell can be secured to the bottom of a Capture Layer in order to harvest light reaching that point;

FIGS. 7A and 7B show a Rectifying Layer placed side by with a Capture Layer to form an embodiment of a solar panel window of the present invention;

FIG. 8 shows how a viewing angle of an embodiment of a solar panel window the present invention affects which exterior objects are visible from inside;

FIGS. 9A-9D show an example of how a solar cell material can be secured to optical prisms that can be used in manufacturing a Capture Layer of the present disclosure;

FIGS. 10A and 10B show an embodiment of a Rectifying Layer having a mirrored surface;

FIGS. 11A and 11B show another embodiment of a Capture Layer of the present disclosure;

FIGS. 12A and 12B show a solar module made using a Capture Layer with a conformal mirror;

FIG. 13 shows a Capture Layer with a conformal mirror separated from the Capture Layer by a lower index layer of material;

FIGS. 14A and 14B shows a molding technique for making a solar module using a Capture Layer where PV cells can be encapsulated during the moulding step;

FIG. 14C shows a perspective view of a mould used in the moulding techniques shown at FIGS. 14A and 14B;

FIG. 14D shows a perspective view of a Capture Layer manufactured using the moulding techniques shown at FIGS. 14A and 14B;

FIGS. 15A-15C show detail on the different layers making up a Capture Layer including a glass front sheet, silicone molded ridges, low index cladding, a mirror coating and PV cells;

FIGS. 16A-16E show a variety of ways glass filler can be employed to use less silicone in building the ridges of a Capture Layer;

FIG. 16F shows a perspective view of the mould of FIG. 16E having glass rods and PV cells placed therein;

FIG. 16G shows a side view of the a Capture Layer obtained from the mould of FIG. 16E;

FIGS. 17A-17C show ways that the glass front sheet can be textured;

FIG. 18 shows a Capture Layer with a low index layer separating the glass front sheet from the ridges;

FIG. 19 shows a Capture Layer made using a dielectric mirror that is chromatically selective and only reflects light usable by the PV cell to make electricity, transmitting infrared light;

FIGS. 20A and 20B show a transmissive deflecting hologram that can be used to shift a capture fan of a Capture Layer;

FIGS. 21A and 21B show a reflecting holographic deflector that can be used as a mirror behind a Capture Layer to shift the capture fan of the Capture Layer;

FIGS. 22A and 22B show a raytrace of a Capture Layer based solar module using a mirror backing;

FIGS. 23A-23C show a raytrace of a Capture Layer based solar module that transmits some light;

FIG. 24 shows plots of light capturing efficiency of the exemplary embodiments of FIGS. 22A, 22B, and 23A-23C, as a function of angle of incidence;

FIGS. 25A and 25B show a Capture Layer based solar module in a roof top, horizontal application;

FIGS. 26A-26D shows a series wiring layout for a Capture Layer based solar module;

FIGS. 27A and 27B show a parallel wiring configuration for a Capture Layer based solar module;

FIGS. 28A and 28B show an electronic billboard assembly comprising a Capture Layer;

FIGS. 29A-29D shows exemplary dimensions and features for a building-integrated solar panel using a Capture Layer and/or a Rectifying Layer of the present disclosure;

FIG. 30 shows side view of an embodiment of a prism of Capture Layer;

FIG. 31 shows a similar Capture Layer embodiment as that of FIG. 18 except without a mirror backing;

FIG. 32 shows a raytrace of a Capture Layer based solar module using a mirror backing;

FIG. 33 shows an exemplary embodiment of a wiring arrangement of PV cells;

FIG. 34 shows another exemplary embodiment of a wiring arrangement of PV cells;

FIG. 35 shows yet another exemplary embodiment of a wiring arrangement of PV cells;

FIGS. 36A and 36B shows an embodiment of PV cells connected in parallel;

FIG. 37 shows an embodiment of PV cells connected in series;

FIGS. 38A and 38B show perspective views of exemplary embodiments of solar panel windows;

FIGS. 39A-39C show exemplary compound capture prisms and examples of solar panel windows using the compound capture prisms;

FIG. 40 shows another exemplary compound capture prism having curved face; and

FIGS. 41A-41C shows another exemplary embodiment of a wiring arrangement of PV cells.

### DETAILED DESCRIPTION OF THE INVENTION

The solar panel window of the present invention differs from prior art solar window products in that it is angularly selective in the light that it absorbs and converts into electricity. Light incident on the solar panel window at pre-determined angles is transmitted through the window substantially unattenuated and undeviated, or with very little attenuation, while light incident from other angles is captured in the solar panel window, which acts as a waveguide. The captured light is concentrated and propagated to solar energy collectors, such as photovoltaic (PV) cells that convert the light into electricity.

The solar panel window can be achieved using a two-layer structure made out of transparent optical material. There is a first layer, referred to as a Capture Layer, which captures sunlight and guides it to PV cells. The second layer, referred to as a Rectifying Layer, redirects light that was deflected but not captured by the Capture Layer. The Rectifying Layer reverses the deflection of the Capture Layer, so that light that is not captured passes through the solar panel window unaltered. The Rectifying Layer is what enables the solar panel window to act as a transparent window. Without the Rectifying Layer, the Capture Layer would still generate electricity but it would distort light passing through the window when viewed straight on. The Rectifying Layer also enables the fabrication of an insulated sealed double pane window, which has better insulating properties than a single layer window.

The Capture and Rectifying layers are substantially complementary in form and can in fact, can be identical in form, with the exception that the Capture layer has PV cells in optical communication therewith.

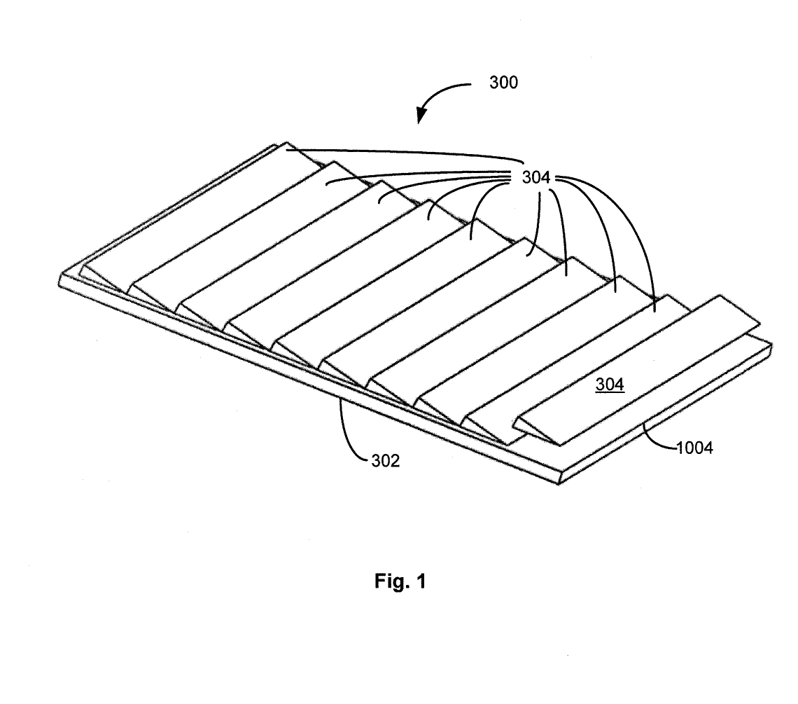

The Capture Layer and the Rectifying Layer can be made of any suitable transparent optical material such as, for example, glass or poly(methyl methacrylate) PMMA, Poly Carbonate, Urethane or Poly-Urethane, Silicone Rubber, or any other suitable transparent optical material, as well as any suitable combination thereof. The Capture layer and the Rectifying layer can form windowpanes that are flat on one face and have repeated saw-toothed ridges on the other face. The layers can be manufactured with a sheet of material between the ridges and the outside face, the sheet having the ridges secured thereto. The sheet and ridges can be manufactured separately and then bonded together, or they can be manufactured simultaneously as one monolithic piece, or made in a moulding process where the prisms are formed directly on a glass sheet. FIG. 1 shows an exemplary Capture Layer 300 of the present disclosure. The Capture Layer has a plurality of prisms 304 secured to a sheet 1004. The rightmost prism 304 is shown spaced apart from the sheet 1004 to illustrate that the prisms 304 can be made as separate pieces from the sheet 1004. Also shown at FIG. 1 is an outside face 302, onto which sunlight impinges (not shown).

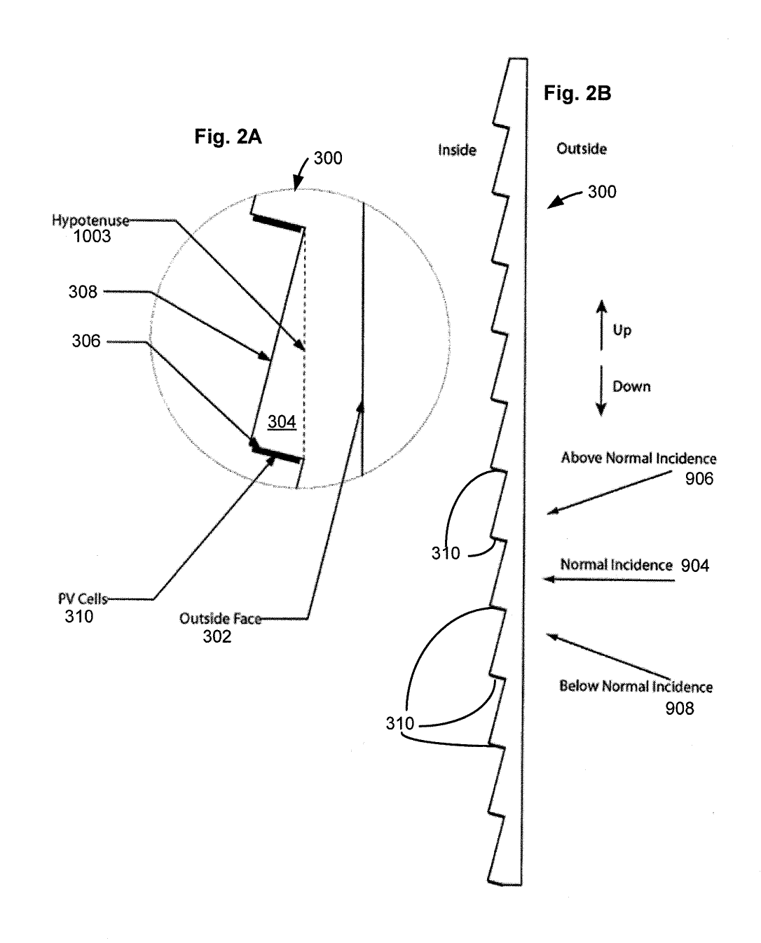

As shown at FIGS. 2A and 2B, the prisms 304, which can also be referred to as ridges, can be substantially identical to each other with each prism defining a linear optic having a right triangle profile, oriented with its hypotenuse 1003 parallel to the outside face 302 of the Capture Layer 300. The ensemble of prisms 304 defines a ridged output surface of the Capture Layer 300. The right triangle has two legs of different lengths. The face made by the shorter of the two legs can be referred to as a collector face 306, and is where PV cells 310 are affixed. The face made by the longer leg can be referred to as a reflective face 308, and is left bare. As will be shown below, the Rectifying Layer of a solar panel window of the present invention can be shaped identically to the capture layer 300, except that it has no PV cells secured thereto.

For the purpose of discussing angles of incidence in the exemplary embodiments below, the orientation of the Light Capture layer 300 shown at FIG. 2B is used. The face of the ridges to which PV cells 310 are affixed, i.e., the collector faces 306, can be referred to as the bottom face of the ridge. The outside face 302 of the Capture Layer is vertical. Normal incidence 904 on the capture layer refers to light traveling horizontally. Light with angles of incidence above normal incidence 906 is striking the panel from above, and similarly light with angles below normal incidence 908 is striking the panel from below.

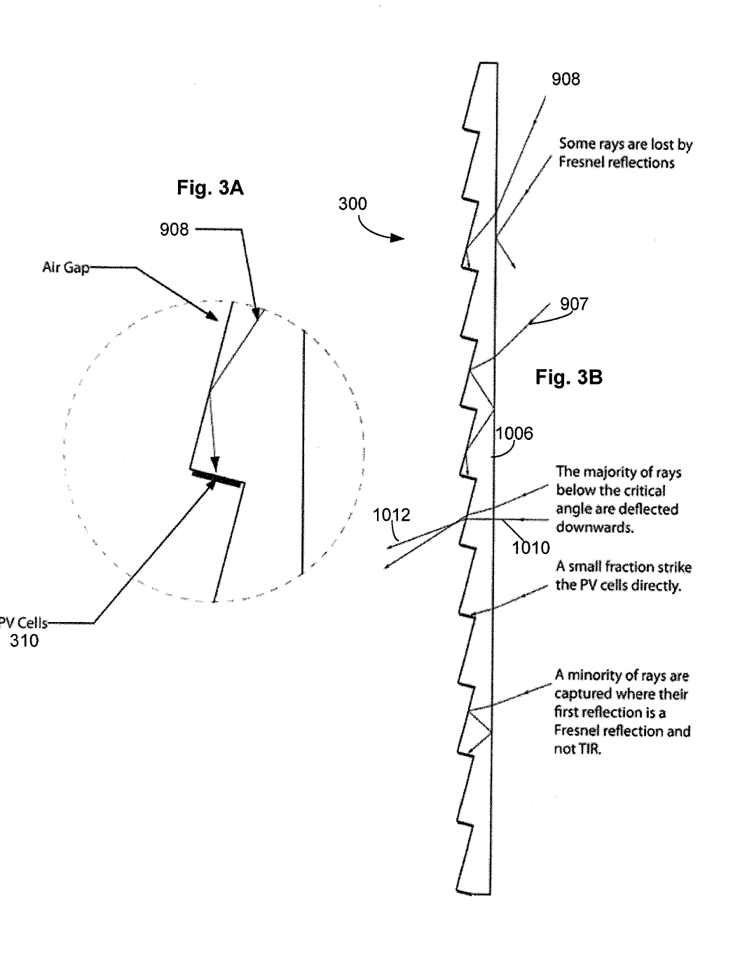

As shown at FIG. 3B, near normal incidence 1010, the Capture Layer 300 deflects the majority of light downwards 1012. Of the light incident on the Capture Layer 300 at or below normal incidence 1010, a small fraction is captured by the Capture Layer 300 through Fresnel reflections. Another fraction of the light incident on the Capture Layer 300 at or below normal incidence 1010 strikes the PV cells 310 directly. As the angle of incidence of light on the Capture layer 300 increases above the normal, the proportion of captured versus deflected light increases. There is a critical angle of incidence beyond which the Capture Layer 300 will capture all light, except the light that is lost at the outside face by Fresnel reflection. This angle is referred to as the critical capture angle (CCA). A ray 907 is depicted as impinging on the outside face 302 at the CCA. The ensemble of prisms 304 defines a ridged output surface of the Capture Layer 300. The input surface 302 and the ridged output surface define a volume therebetween, which is substantially homogenously filled by the material making up the Capture Layer 300.

The CCA depends on the ratio between the lengths of the long and short legs of the right triangle that forms the ridges (i.e., the length ratio of the reflective face 308 and of the collector face 306), on the index of refraction of the material used to make the Capture Layer 300, and on the index of refraction of the material which surrounds the Capture Layer 300 (this material can be, for example, air). When the index of refraction of the Capture Layer 300 is 1.5, and the leg ratio between the long and short legs is 4:1, and the Capture Layer 300 is in air, then the CCA is about 45 degrees measured from the normal of the panel. The Capture Layer 300 of FIGS. 3A and 3B has these exemplary characteristics. In this scenarios a ray 908 that impinges on the Capture Layer 300 at an angle greater that the CCA and is trapped in the Capture Layer.

Changing the ratio between the lengths of the legs of the ridge (prism 304) changes the CCA. For a Capture Layer made of a material with an index of refraction of 1.5 and with leg ratios of 2:1, 3:1, and 5:1, the CCAs are approximately 24 degrees, 37 degrees, and 50 degrees respectively. Decreasing the leg length ratio reduces the CCA leading to more light being captured overall, however it requires the use of larger PV cells 310 to cover a given window area. Increasing the index of refraction also decreases the critical capture angle. For example, a Capture Layer made using a material with an index of refraction of 2.0 and a leg ratio 4:1 has a critical capture angle of 33 degrees. However, there is less design flexibility in this design variable, because most optical dielectrics and polymers have indices of refraction close to 1.5. Additional details on the CCA for different embodiments of the present disclosure are discussed further below.

The solar panel window of the present invention can act essentially as a non-tracking concentrating solar panel. The optics of the Capture Layer 300 concentrate incident sunlight onto PV cell strips where the light is absorbed and converted into electricity. These PV cells strips have less area than the Capture Layer's outside face 302. As such, less PV material is used than would be if the PV material were used to absorb the sunlight directly.

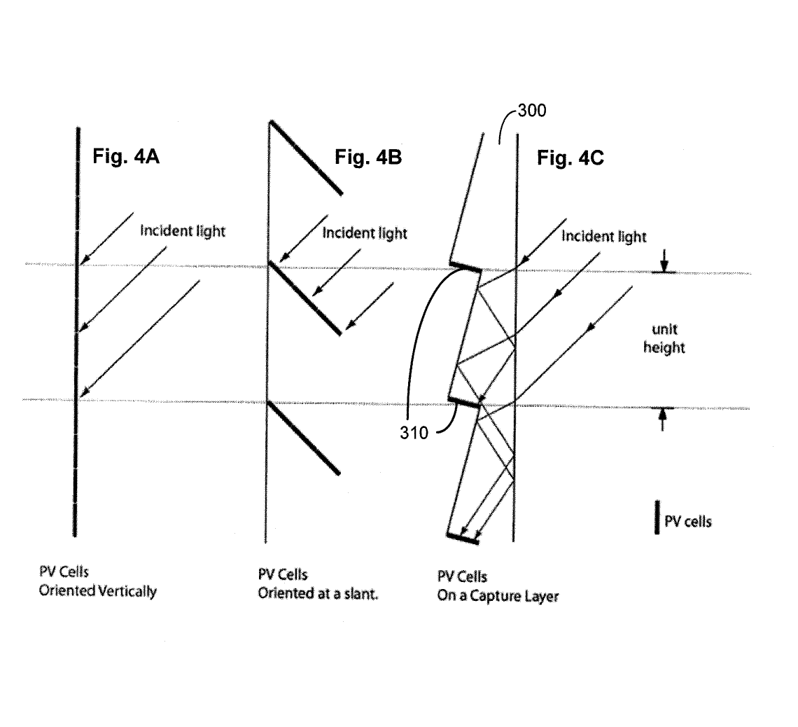

FIGS. 4A-4C show examples of how sunlight incident from 45 degrees above horizontal can be absorbed by PV cells. The example at FIG. 4A shows PV cells oriented vertically—as would be the case if a solar panel were positioned vertically. The example of FIG. 4B shows how PV cells can be positioned at a 45-degree slant to absorb sunlight directly; in this orientation the light hits the PV cells with normal incidence. As will be understood by the skilled worker, positioning PV cells such that light impinges thereon at normal incidence is an optimal orientation, employing minimum PV material to absorb the light directly. The example of FIG. 4C shows the Capture Layer 300 using ridges with a 4:1 leg ratio and a CCA of 45 degrees with relatively small PV cells 310 attached thereto. The Capture Layer 300 is concentrating sunlight onto the PV cells 310. Per unit height, the Capture Layer 300 employs roughly four times less PV material than the vertically oriented panel (FIG. 4A) and almost three times less PV material than the slanted solar panel (FIG. 4B). The intensity of sunlight incident on the PV cells 310 secured to the Capture Layer 300 of FIG. 4C is three times more intense than the intensity of sunlight incident on the slanted solar panel of FIG. 4B.

The Capture Layer 300 does not function as a solar panel when sunlight is incident at an angle normal to the Capture Layer 300. In this instance the Capture Layer 300 only deflects light downward as shown at FIG. 3B. The Capture Layer 300 functions as a solar concentrator when the angle of incidence of the light is above the critical capture angle, as described above.

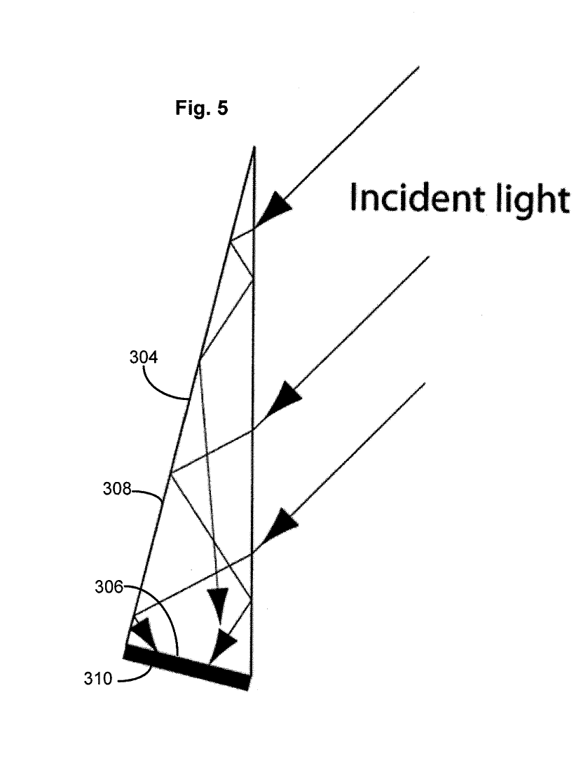

The action of the Capture Layer optics is due to the shape of ridges (prisms 304). These ridges acting alone are concentrators with the same concentration as the whole Capture Layer. This is shown at FIG. 5.

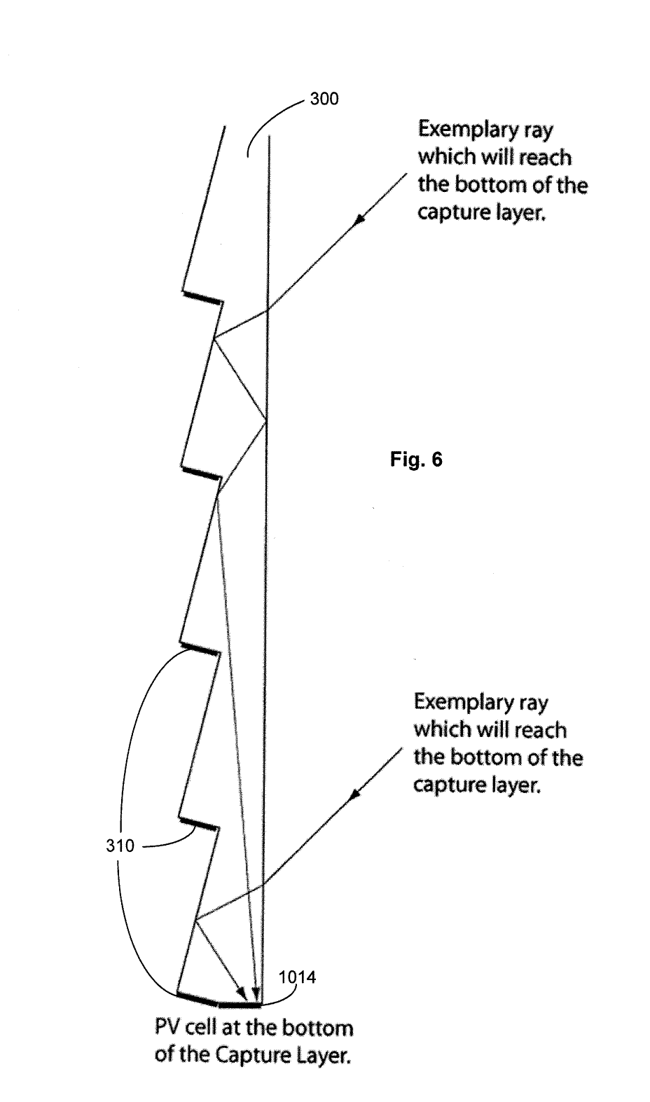

The sheet 1004 (shown at FIG. 1) to which the prisms 304 are secured is not purely structural. It is transparent, and light can travel inside the sheet 1004 as well as within the ridges 304. Some light can miss the PV cells on the ridges and reach the bottom of the sheet 1004. A PV cell strip 1014 can be placed here to capture the light as shown at FIG. 6.

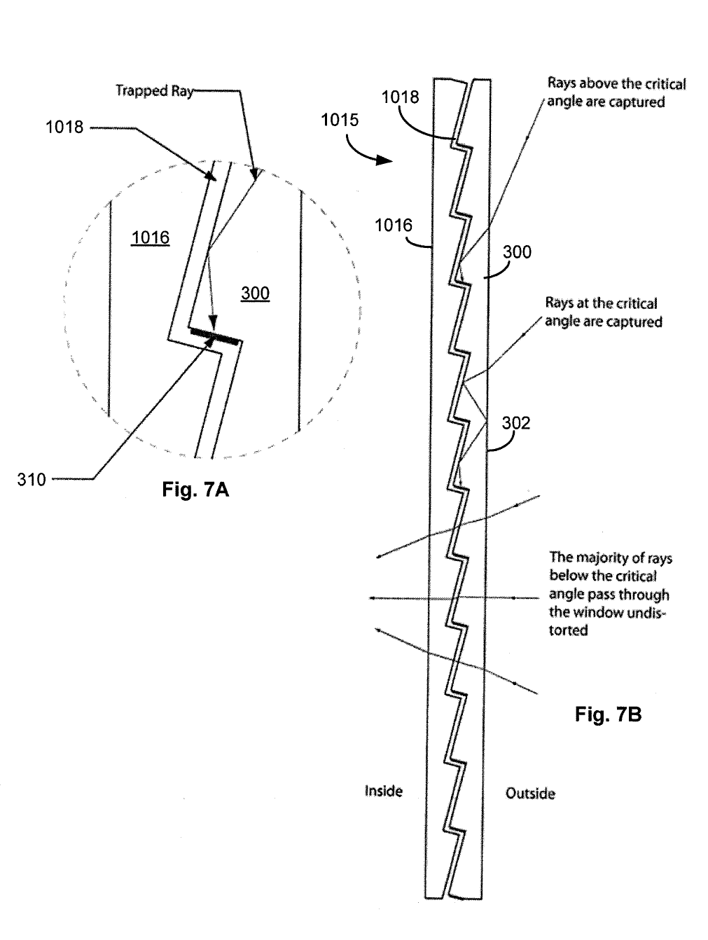

FIGS. 7A and 7B show an embodiment of a solar panel window (SPW) 1015 of the present invention. As shown at FIG. 7B, a Rectifying Layer 1016 of the SPW 1015 can have the same shape as the Capture Layer 300 but without PV cells. In any case, the Light Rectifying Layer 1016 and the Light Capture Layer 300 should have substantially complementary shapes. The Rectifying layer 1016 is positioned next to the Capture Layer so that the ridges of each layer quasi-interlock. A small gas-filled gap 1018 is present between the Light Capture layer 300 and the Light Rectifying layer 1016. The gap 1018 allows total internal reflection in the Capture Layer 300 to occur and it also provides improved insulation for the window, as in double pane windows. The Rectifying Layer 1016 and the Capture Layer 300 can be secured together using any suitable mechanism such as those used to secure to each other, glass panes of a double pane window.

The Rectifying Layer 1016 reverses the deflection that occurred at the Capture Layer 300 for light that was not captured by PV cells 310. Because the ridge faces of both layers are substantially parallel, the deflection that occurs when light exits the Capture Layer will be reversed on entering the Rectifying Layer. No net deflection will occur and the SPW 1015 will transmit light substantially undistorted. If the gap 1018 is made very large then some distortion will occur, and some color separation will also occur. In cases where these effects are undesirable, the gap should be kept small.

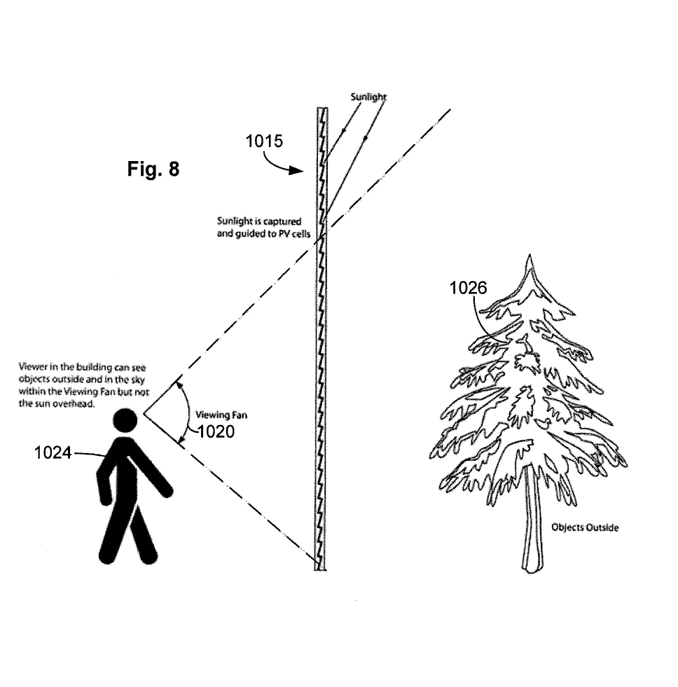

FIG. 8 shows a Viewing Fan 1020 within which the SPW 1015 is transparent to a viewer 1024. At angles outside the Viewing Fan 1020, the SPW 1015 appears opaque. In the example of FIG. 8, the solar panel window 1015 uses prisms with a 4:1 leg ratio and the 45-degree critical angle example described above. The example shows a person 1024 looking out a window with the sun overhead. Because the whole tree 1026 is within the viewing fan 1020, it will be completely visible through the window, but the sun that is overhead will be invisible to the person 1024 and the direct sunlight will be captured by the window and guided to the PV cells. The viewer will see thin horizontal lines in the window where the PV cells are located, but these will not meaningfully obstruct the view. Looking up towards the sun the viewer will observe what appears to be an awning outside the window.

The solar panel window 1015 described above can be made from any suitable material in any suitable way. Whole Capture Layers 300 and/or Rectifying Layers 1016 having ridges (prisms 304) included could be moulded, or cast out, of a material such as, for example, PMMA, Poly Carbonate, Poly Urethane, Silicone, or Glass. The layers could also be extruded whole, out of the same material.

Alternatively, molding, extruding or forming by any suitable means the ridges (prisms 304) alone out of glass or a polymer material, and then affixing them to flat windowpanes by any suitable means such as, for example, by using an optical epoxy, or curing the parts in an oven with an intervening sheet of Ethylene vinyl acetate or Polyvinyl acetate to bond them using a curing process. Any other suitable lamination technique could be used to connect the prisms to the glass sheet and make the Capture Layer. The ridges could even be held in position against the sheets mechanically, so that no chemical bond exists between the ridges and the sheets of the layers. Regardless of the manufacturing method, both the Capture Layer 300 and the Rectifying Layer 1016 can be manufactured in the same way.

As described above, the Capture Layer 300 requires the addition of PV cells 310, which can be any suitable type of photovoltaic cells such including crystalline semiconductor based, thin film based, or organic materials based. The PV cells 310 can be manufactured and encapsulated, with or without a supporting substrate or superstrate, and then attached to the Capture Layer ridges (prisms 304) through any suitable means such as, for example, by using optical epoxy, silicone, mechanical holds, or by any other suitable means.

The PV cells 310 can also be built directly on the collector face 306 (short leg of prism 304). This can involve soldering a pre-determined number of PV cells 310 in series to obtain a PV cell assembly (“PV cell assembly” can be used interchangeably with the expression “PV cell” or “PV cell strip”) that extends along the long dimension (typically the width of the Light Capture layer 300) of the collector face 306. The collector face 306 can be primed with encapsulating material, then the PV cell assembly can be positioned against the collector face, and a second application of encapsulating material can be applied to the backside of the PV cells 310 to completely encapsulate them.

Depending on the PV cell encapsulation material used, the Capture Layer 300 will have to remain in place for a period to allow the encapsulant to set. Once it is set, the Capture Layer 300 can be juxtaposed to a Rectifying Layer 1016 using any suitable approach such as, for example, approaches used to connect double pane windows together. These involve the use of aluminum or plastic spacers to separate the glass panes. The panes are hermetically bonded to the spacers using a butyl based bonding agent and secured in place using a silicone sealant. A desiccant can be placed inside the cavity created in order to absorb any incidental moisture which enters the cavity during fabrication or during use. In the case of a Solar Panel Window, an aluminum or plastic extrusion could be used as a spacer and be bonded to the outer edges of the Capture Layer 300 and the Rectifying Layer 1016 using an butyl agent to create a seal against moisture and a silicone sealant to mechanically hold them together and maintain a gap therebetween. The extrusion houses a desiccant to keep moisture from accumulating in the space between the windows. Dry air, or another insulating gas such as argon, can be injected into the space between the windows.

The SPW 1015 will typically have wires or electrical connections at one or more of its outside edges. The strips of PV cells 310 have conductors connecting the individual PV cells 310 to each other to form a series of PV cells (PV cell assembly). Wires connected at one end to the strips of PV cells 310 can be routed down the edges of the solar panel window 1015 in the aluminum extrusions to exit at the base of the window for connection to any suitable circuitry that uses or stores electricity. The area where the wires exit or where an electrical connector is located can to be sealed against moisture.

As stated above, the PV cells 310 can be affixed in any suitable way to the ridges (prisms 304), in particular on the collector faces 306 of the prisms 304, of the Capture Layer 300 either before or after the ridges are affixed to the sheet of the Capture Layer. Likewise, the ridges can be formed by any means including extrusion of PMMA, Poly Carbonate, Poly Urethane, Glass, Silicone, or moulding from any of the aforementioned materials or simply by grinding out of glass.

PV cells 310 can be secured to many ridges simultaneously. In such an approach, the ridges (prisms 304) can be formed and then braced together so that the collector face 306 of all the ridges are in a same plane and flush with one another. Alternately, many ridges can be formed as one piece so that the PV faces of adjacent ridges would be joined together by thin sections of material.

The goal of combining the ridges like this is to create a large, flat surface, to which PV cells 310 can be applied. Performing the same processing steps to many ridges simultaneously saves time and money, and furthermore, by increasing the size of the area to which PV cells 310 are applied enables the use of conventional PV cell application processes.

For example, PV cells can be applied to the collector faces 306 of the ridges in a thin film deposition process such as vacuum deposition. The technical difficulty of applying thin film PV cells to the PV faces of the ridges is not be very different from that of applying thin film PV cells to a glass sheet because in both cases the face to which the PV cells is applied is flat.

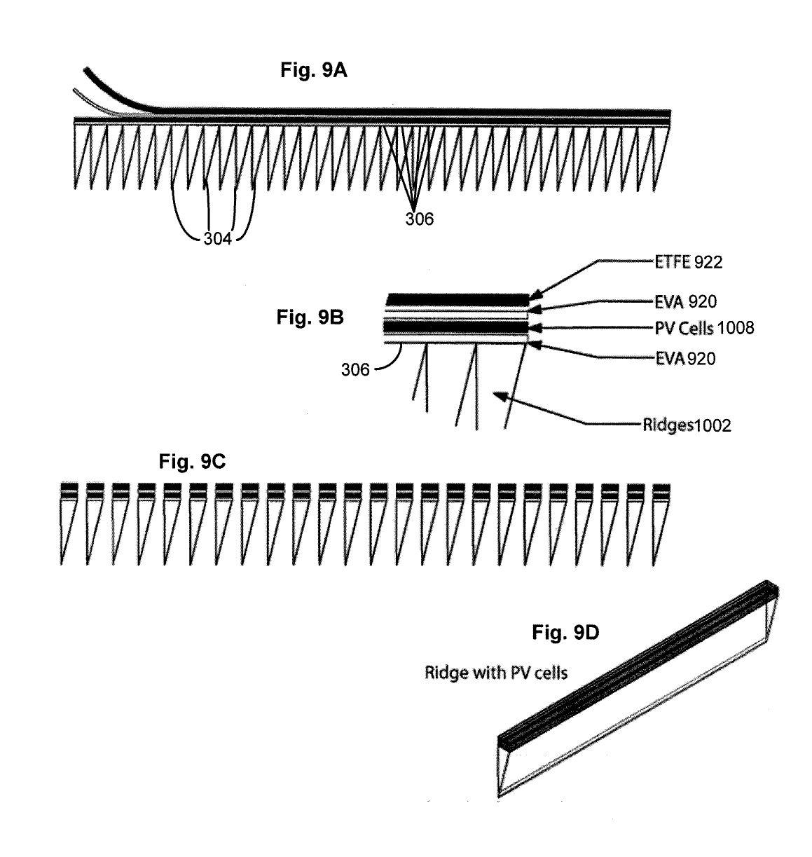

With respect to FIG. 9A-9D, as another example, a process such as PV cell encapsulation using Ethylene-vinyl acetate (EVA) 920 and Ethylene tetrafluoroethylene (ETFE) 922 can be used. PV cells 310 are placed between two sheets of EVA 920 on the collector face 306. The PV cells 310 can be soldered together in series before being positioned between the EVA 920 sheets. A sheet of ETFE 922 can be placed on top of the EVA 920, and the whole stack placed in a curing oven.

Afterwards, the ridges (prisms 304) need to be separated so that they can be used to make a Capture Layer 300. This requires cutting, breaking, or cleaving any material bonds that formed during the PV cell application process, as well as adjoining PV cells themselves, but this can be very simple. One can employ, for example, either diamond tipped circular cutting tools, laser cutting, or one can simply snap the ridges apart.

Once the ridges are finished, they can be mounted on a sheet of optically transmissive material 1004 to make the Capture Layer 300 of, for example, a SPW 1015. As will be understood by the skilled worker, the ridges would need to be wired so that the electricity they produce could be extracted from the module. The ridges can be mounted in any suitable manner used for glass lamination processes including using epoxies, silicone, polyvinyl acetate (PVA) or ethylene-vinyl acetate (EVA) and using any curing method including Ultra Violet light curing, heat curing, or multi-component adhesives that are mixed before application and can react and cure at room temperature.

As will be understood by the skilled worker, a third layer of glass (not shown) can be used to increase the insulation of a SPW. This layer can be added to the interior of the window or to the exterior of the window.

The SPW 1015 can be adapted to make a Solar Wall Panel, which is an apparatus that does not transmits light and which functions as a building clad in places on a building where there are no windows, and where vertical solar panel type apparatus is desired. While the SPW 1015 described above can be applied in this situation, the CCA attributable to the SPW 1015 can be reduced substantially for a Solar Wall Panel by, for example, applying a reflective coating to the ridged side (ridged input surface) of the Rectifying Layer 1016.

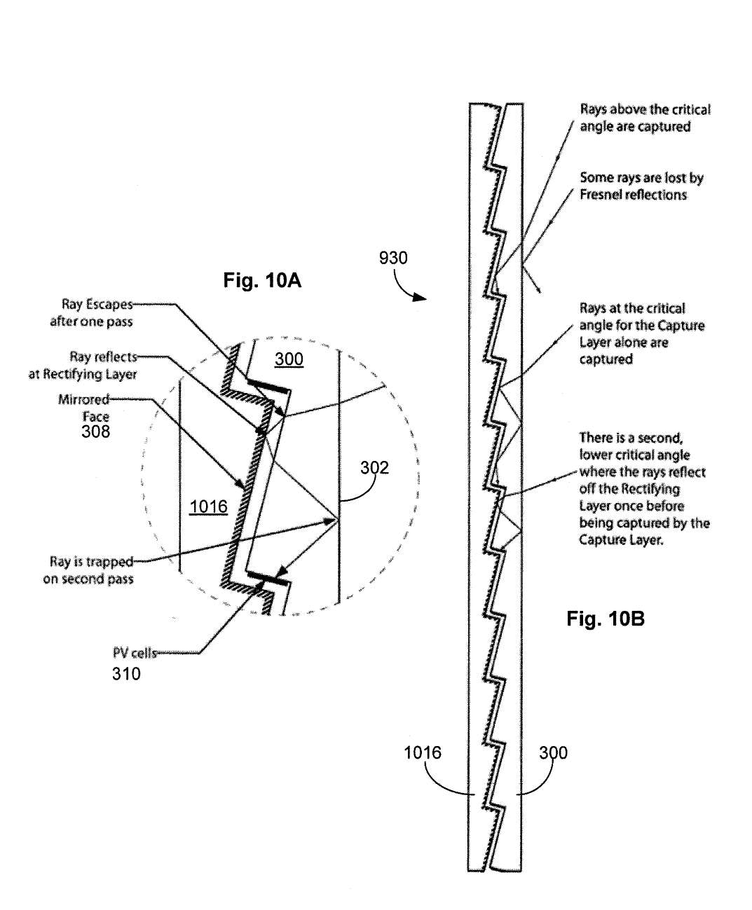

Adding such a reflecting layer reduces the critical capture angle for the Capture Layer by causing light that would, in a SPW, be deflected out of the Capture Layer 300 and transmitted through the Rectifying Layer 1016, to propagate for a second time in the Capture Layer 300. On this second pass, there is another opportunity for light capture. As previously described, a SPW 1015 that has an index of refraction of 1.5 and a leg ratio of 4:1, has a CCA of 45 degrees (this CCA can be referred to as a first CCA). If a mirror coating is applied to the ridges of the Rectifying Layer 1016, the resulting panel has a critical capture angle of 21 degrees (this CCA can be referred to as a second CCA). This embodiment is shown at FIGS. 10A and 10B where a Solar Wall Panel 930 is depicted with its Rectifying Layer 1016 having a mirrored face 932, which comprises the ridged input face of the Rectifying Layer 16 and a mirror.

While in principal the mirror coating 932 could be added directly to the Capture Layer 300, forgoing the Rectifying Layer 1016 altogether, there is a disadvantage in having the mirror on the Capture Layer 300. Reflections due to total internal reflection (TIR) are nearly 100% efficient. Conversely, reflections off metallic mirrored faces are relatively inefficient. Aluminum mirrors reflect with approximately 84% efficiency weighed across the relevant spectrum for solar powered photovoltaics. Captured rays can undergo many reflections in the Capture Layer 300 before reaching the PV cells 310. If the bare ridges (reflective face 308 at FIG. 5) of the Capture Layer 300 were coated with an 84% efficient Aluminum mirror, each reflection would reduce the power of light available by 16%. For example, a ray that reflects three times off a mirrored surface will be reduced to 59% of its original intensity. For this reason, it is advisable to have an air gap between the mirrored surfaces and the Capture layer, so that light only needs to reflect once off the mirrored surfaces at most, and thereafter is reflected by very efficient TIR until it reaches a PV cell 310. This one reflection will cause an attenuation of no more than 16%.

The solar panel windows and solar panel walls have been illustrated in a vertical orientation; however they can be deployed in any other suitable orientation such as a horizontal orientation or an oblique orientation without departing from the scope of the present invention.

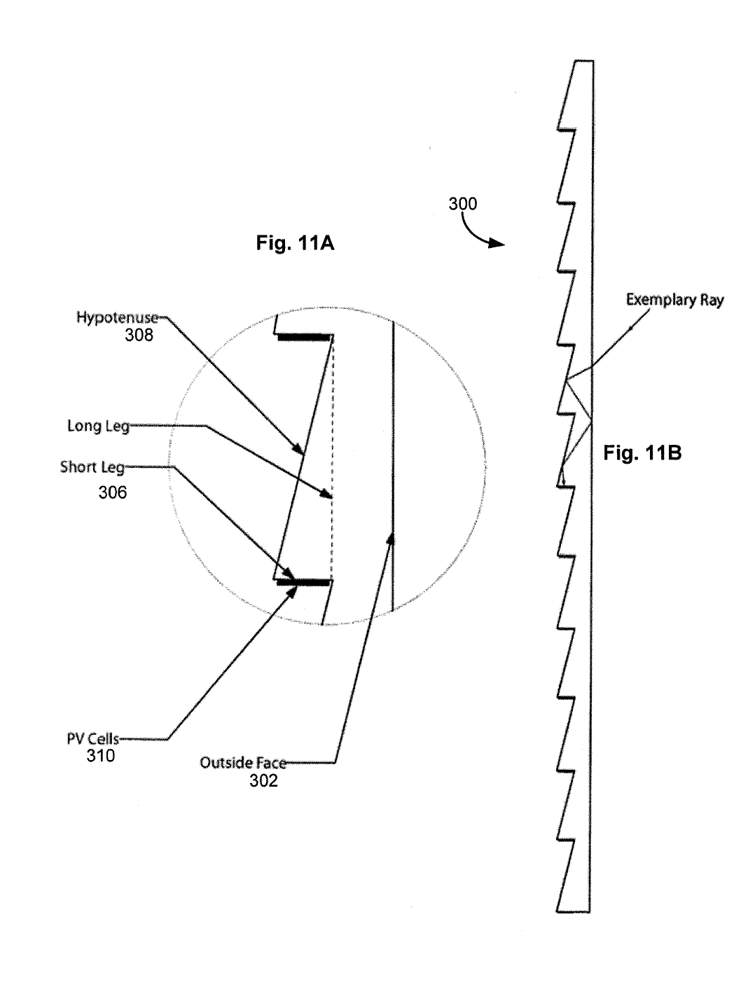

The ridges (prisms 304) shown in all the figures have been shown to use right triangles. However, other types of triangles can be used. One possibility is to employ a right triangle with its hypotenuse being the bare face (reflector face 308) of the ridge (prism 304). The PV cell 310 still sits on the short leg (collector face) of the triangle, and the long leg is now oriented parallel with the outside face of the layer 302. This arrangement, shown at FIGS. 11A and 11B, works in the same manner described above in relation to FIG. 3A. However, the PV cells 310 now sit flat and so they present a narrower profile to a viewer, leading to fainter black lines in the solar panel window. Only the Capture Layer 300 is shown at FIGS. 11A and 11B; the corresponding Rectifying Layer would have the same shape (complementary shape) but without the PV cells 310. As will be understood by the skilled worker, triangles other than right triangles could also be used.

It may be desirable to control the transparency of SPWs, as well as the amount of sunlight that they allow through versus being captured and converted to electricity. This can be done in different ways. In a first example, if one wishes for some light above the critical capture angle to pass through the window, one could simply remove, e.g., every other ridge from the window. This would make a partial solar panel window that would admit more light but produce less power. In a second example, if one wishes to make a darker window that produces more electricity, then every other ridge of the Rectifying Layer 1016 could have a mirror coating. This would reduce the light that passes through the window by 50%, but it would also decrease the critical capture angle for 50% of the light striking the window—that portion striking in front of where the Rectifying Layer is mirrored—so the panel would produce more electricity. As will be understood by the skilled worker, one can remove ridges or add mirror coatings in order to reach a desired balance between admitted light and electricity production.

Alternatively, instead of placing PV cells 310 on the PV faces (collector faces 306) on the ridges of the Capture Layer 300, the PV faces can simply be painted black to absorb light impinging thereon. This would result in a window that appears clear to look through, but would not admit sunlight from above the CCA. This could be desirable from a standpoint of reducing cooling costs for buildings, and essentially replace the need for window blinds to create shade.

Manufacturing SPWs can be relatively simple and add only a few additional steps to typical manufacturing methods of double pane windows. This can be achieved by starting out with a double pane window that has an air gap of sufficient size to accommodate ridges (prisms 304) on each of the windowpanes. The ridges, with PV cells already secured thereto, can be fixed to glass of the windows using a small quantity of epoxy that would be hidden by the trim around the window. The window trim can be altered slightly to allow for the wires connected to the PV cell strips to exit the SPW; these wires can all be hidden view and/or incorporated into the trim. Alternatively, any other suitable process can be used to laminate the prisms to the glass sheet, as previously described.

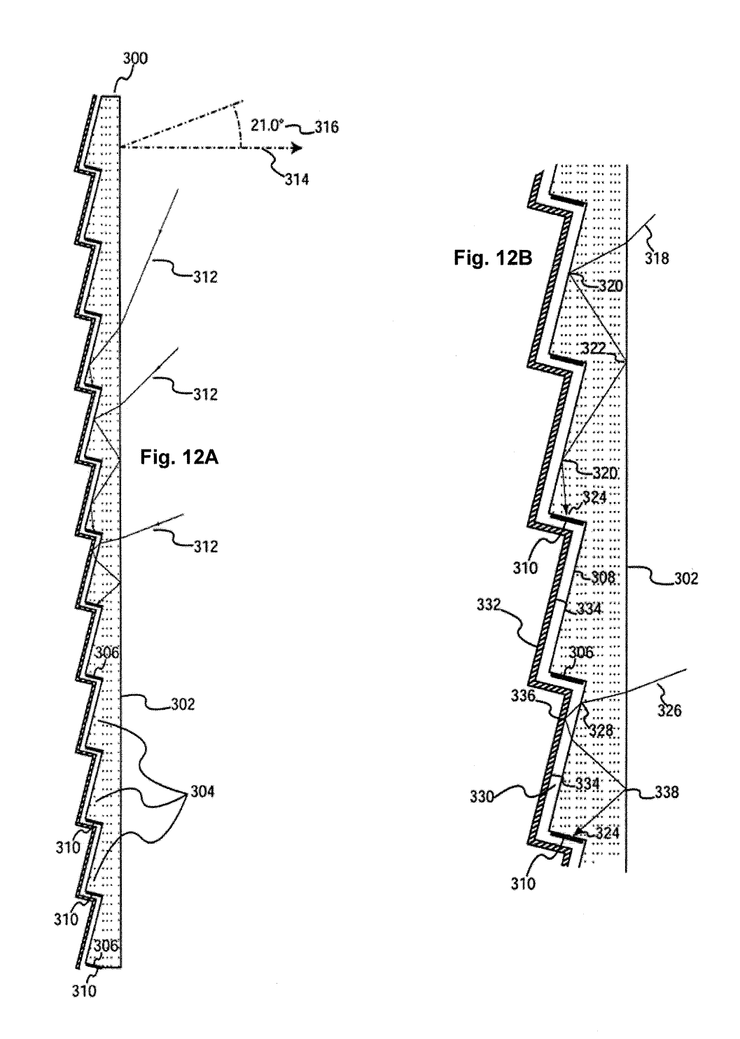

As described above in relation to FIGS. 10A and 10B, if the Rectifying Layer 1016 is coated with a mirror film, the solar panel window 1015 becomes an opaque solar panel that captures light at a lower CCA (referred to as the second CCA). Such a panel can be made by either mirror coating the Rectifying Layer or by using a mirror that conforms to the capture layer, as shown at FIGS. 12A and 12B.

At FIG. 12A, the Capture Layer 300 can be made of an optical material, such as glass, PMMA, polycarbonate, silicone, or any other suitable optically transmissive material. Most typical optical materials have an index of refraction of approximately 1.5. The Capture Layer has a flat collector face 302 and a plurality of ridges (prisms 304). The prisms 304 have small facets (collector faces 306) and large facets (reflector face 308). PV Cells 310 are secured to the collector faces 306. The Capture Layer 300 redirects and guides incident light 312 impinging on the outside face 302 from any angle, measured from the surface normal of the collector 314, above a critical capture angle 316. The captured light is guided to the PV cells 310 where the light is absorbed and converted into electricity.

Some captured light, such as ray 318 shown at FIG. 12B reflects 320 by total internal reflection (TIR) off the reflective face 308 and also reflects 322 by TIR off the outside face 302 before it strikes 324 a PV cell 310 where it is absorbed. For the ray 318 shown, there are only three bounces, however, other rays can potentially reflect hundreds of times (or any number of times) before encountering a PV cell, others only reflect once and others never reflect prior to encountering a PV cell.

Other rays such as 326 will not reflect by TIR at the first encounter with the reflective face 308, instead they will deflect 328. They then encounter, after an air gap 330, a mirror 332. This mirror has facets 334 that are substantially parallel to the reflective faces 308. This mirror 332 can be produced by mirror coating a Rectifying Layer, as described before. It can also be produced using a conformal mirror, which follows the form of the capture layer ridges 304 or, by using a stiff mirror such as one made out of folded aluminum.

The ray 326 reflects 336 off the mirror facet 334. This causes the ray to pass through the Capture Layer 300 for a second time and enables reflection 338 by TIR off the outside face 302. Once a ray has reflected by TIR off either the outside face 302 or one of the reflective faces 308, the ray is captured and will strike 324 a PV cell 310.

Because the reflections off the reflective faces 308 can be multiple for some light, it is better if these reflections are total internal reflections and not reflections off a mirror coating formed directly on the large facets 308. This is because total internal reflections reflect 100% of the incident light, whereas mirrors can have some inefficiency and absorb some light. An aluminum mirror, for example is 84% efficient. This means that 84% of the incident light is reflected, and the mirror absorbs 16%. After two reflections off an aluminum mirror light intensity is reduced to 71% of it's initial intensity (71%=84%×84%). After four reflections off an aluminum mirror with 84% efficiency light intensity is reduced to 50% of its initial intensity.

For this reason, a conformal mirror in intimate contact with the capture layer is not optimum. Such an intimate contact would include a mirror coating applied to the Capture Layer 300 or a mirror bonded to the Capture Layer using an optical adhesive with the same index of refraction as the Capture Layer. Both of these arrangements would create a situation where the mirror would absorb light on every single reflection off the reflective faces 308.

Instead, any mirror employed can have an air gap 330 between the reflective faces 308 and the mirror facets. With an air gap, light reflects only once off the mirror, and then it reflects by total internal reflection off the outside face 302. Once trapped inside the Capture Layer 300, the light reflects off the outside face 302 and the reflective face 308 by total internal reflection only. Some light never reflects off the mirror and reflects only by total internal reflection during the capturing process and while it is trapped and propagated to the PV cells 310.

The mirror shown in the previous image can be any suitable mirror including a Mylar mirror, an aluminum mirror, and a mirror coated polymer film or sheet, a multilayer dielectric stack mirror, or any suitable reflective sheet material. Additionally, the mirror can be made by mirror coating a ridged structure such as, for example, a rectifying layer structure.

In practice, maintaining a dry air gap can be difficult. Instead of an air gap, it is possible to introduce a non-gaseous, optically transmissive, low-index material between the Capture Layer 300 and the mirror. This material can have an index of around 1.3 or 1.4 (for example fluorinated PMMA can have an index of 1.35 and Sylgard™ 184 has an index of 1.42), but in any event lower than the principal index of refraction of the Capture Layer of approximately 1.5. Total internal reflection still occurs at the interface between the high index and low index material.

An arrangement employing an intervening low index optical material before the mirror will have the same critical capture angle as the arrangement using the air gap before the mirror. The index of the intervening material will determine the maximum number of reflections off the mirror that can occur before total internal reflections take over.

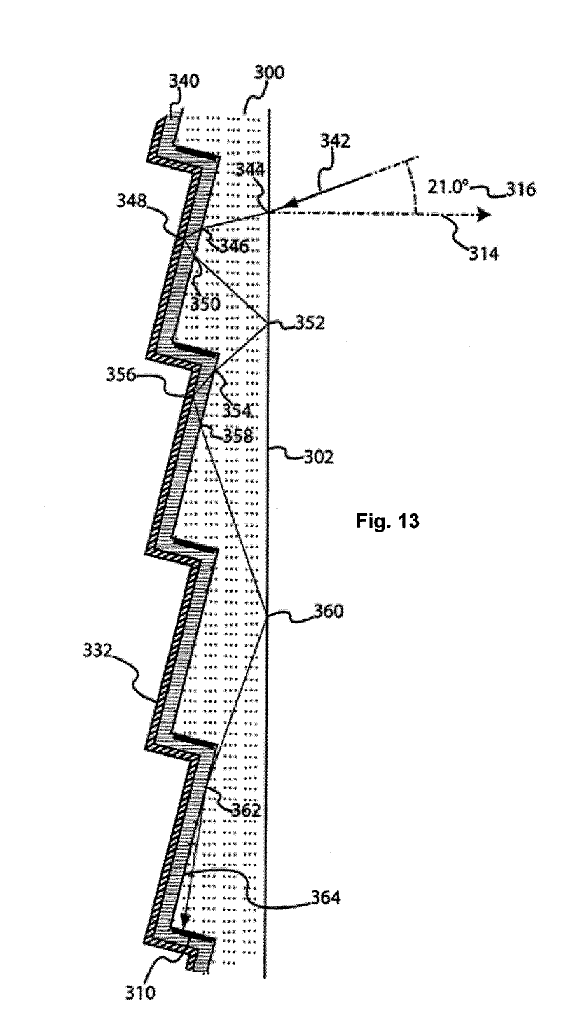

A case where the capture layer has an index of refraction of 1.5 and the optical material between the capture layer and the mirror has an index of 1.4 is shown at FIG. 13. The capture layer 300 (with an index of refraction of 1.5) is separated from the mirror 332 by a layer of lower index material 340 (with an index of refraction of 1.4). The CCA 316 (which can be referred to a the second CCA) is 21 degrees from the surface normal 314 of the capture layer.

A ray 342 at the critical angle deflects 344 on entering the capture layer 300. It is then deflected again 346 on entering the lower index material 340 and reflects 348 off the mirror 332. It deflects 350 again on re-entering the capture layer 300. It totally internally reflects 352 off the outside face 302. It then deflects again 354 on entering the lower index material 340. Once again it reflects 356 off the mirror 332, deflects 358 on re-entering the capture layer 300 and totally internally reflects 360 off the outside face 302 of the capture layer 300. It then totally internally reflects 362 off the interface 364 between the capture layer 300 and the lower index material 340, and strikes the PV cell 310.

Some rays will reflect off the mirror 332 less than twice before striking a PV cell, but no rays above the critical capture angle 316 will reflect off the mirror more than twice given the exemplary design of FIG. 13. Without the lower index layer 340 separating the mirror from the Capture Layer, that is, if the mirror were in intimate contact with the capture layer, some rays could potentially reflect multiple times off the mirror, and this would dramatically reduce the system's overall efficiency at conducting light to the PV cells.

The lower index material can be any material with a lower index of refraction than the capture layer. At FIG. 13, the lower index material 340 has an index of 1.4; however, a material with higher index or lower index could also be used provided that it has a lower index of refraction than the remainder of the optical material in the Capture Layer 300. Potential material combinations are described below.

A Capture Layer could easily be moulded out of a variety of optical polymers, such as polymethyl meth-acrylate (PMMA) and polycarbonate (PC) using any conventional moulding processes such as, for example, injection moulding, extrusion, compression moulding. However, there can be difficulties in using such polymers to form a capture layer. Polycarbonate is known to yellow during exposure to UV light, which would be undesirable for a solar power product. PMMA is flammable and thus might not be desirable as a product for building windows. Silicone and glass are more appropriate materials for building integrated solar modules being flame retardant. Other polymers, including, for example, PMMA, Polycarbonate and Polyurethane might also be used but then it might be required to include flame retardant additives or ultraviolet blockers to the material formulation in order to ensure good operation and conform with building codes in the market in question.

A fabrication method for the present invention is to mould silicone over sheets of glass. Moulded Silicone has very glass like properties except that it is softer and more pliant. Further, moulded silicone can be used to encapsulate and protect PV cells from moisture.

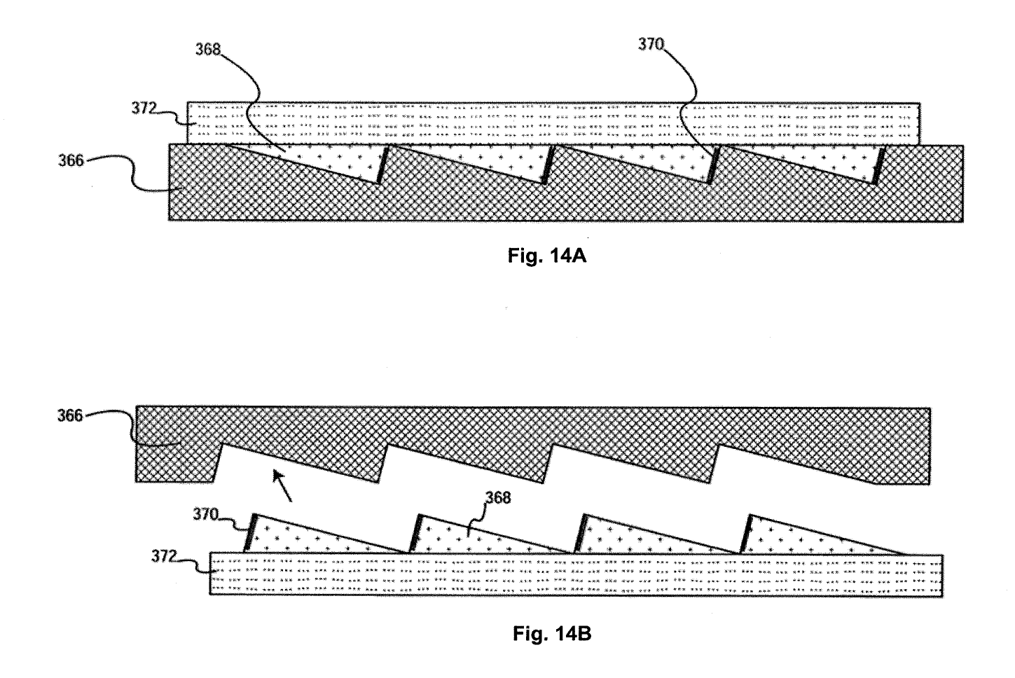

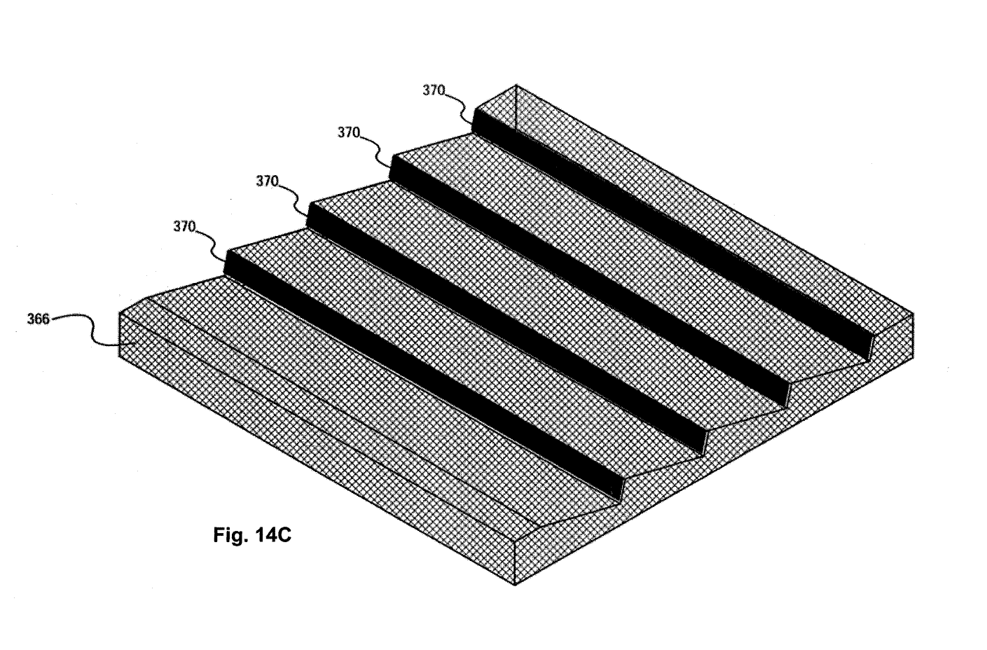

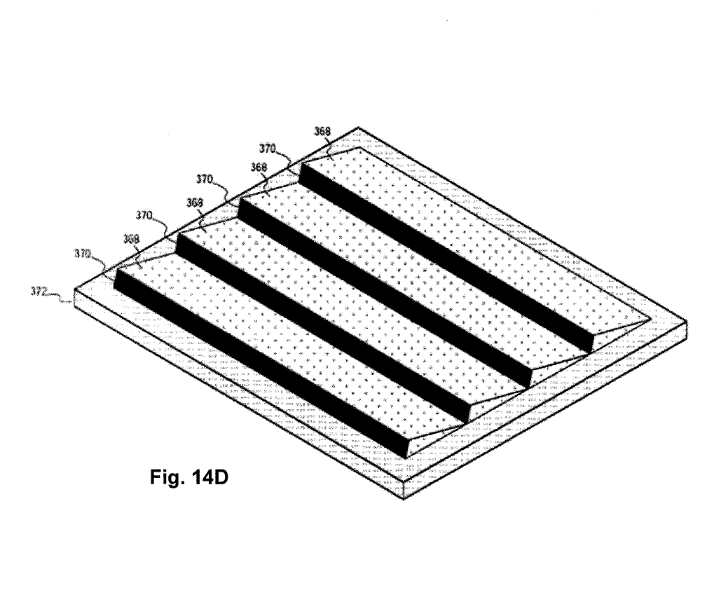

An example of silicone moulding is described in relation to FIGS. 14A-14D. A mould made of polished steel 366, optionally with a nickel coating, is filled with uncured silicone 368 and PV cell strips 370. Subsequently, a sheet of glass 372 is placed on top to close the mould and is pressed against the silicone. The mould would be heated rapidly to high temperature, for example, in the range of 100 to 200 degrees Celsius, to cure the silicone 368. The mould could also be made of a material other than steel, for example, PMMA can be used to make a mould as Silicone does not adhere to PMMA. Cast PMMA sheet is extremely smooth and does not need to be polished, and can be used to make a mould which will transfer the high degree of polish to the material being moulded. Materials other than silicone can also be moulded in this way, including but not limited to poly(methyl methacrylate), polycarbonate, urethane, and poly-Urethane.

It is not necessary for the silicone 368 to completely cure before the mould can be removed; a partial cure would be sufficient. Full cures can take 24 hours so requiring that silicone fully cure in the mould could be undesirable for mass manufacturing; however it could still be used. As shown at FIG. 14B, the mould 366 and glass 372 can be flipped over and the mould lifted off before (or after) a full cure was complete. FIG. 14C shows a perspective view of the mould 366 with the PV cell strips 370 in place (however, lateral sides of the mould, preventing running of silicon outside the mould, are not shown). A glass sheet can placed over the mould, and silicone is pumped or poured in to fill the mould. FIG. 14D shows the outcome of the process: a capture layer with PV cell strips 370 located along silicone ridges 368 attached to a glass sheet 372. Instead of a pump-based approach, a vacuum can be used to draw air out of the mould and draw the silicone resin or other polymer into the mould.

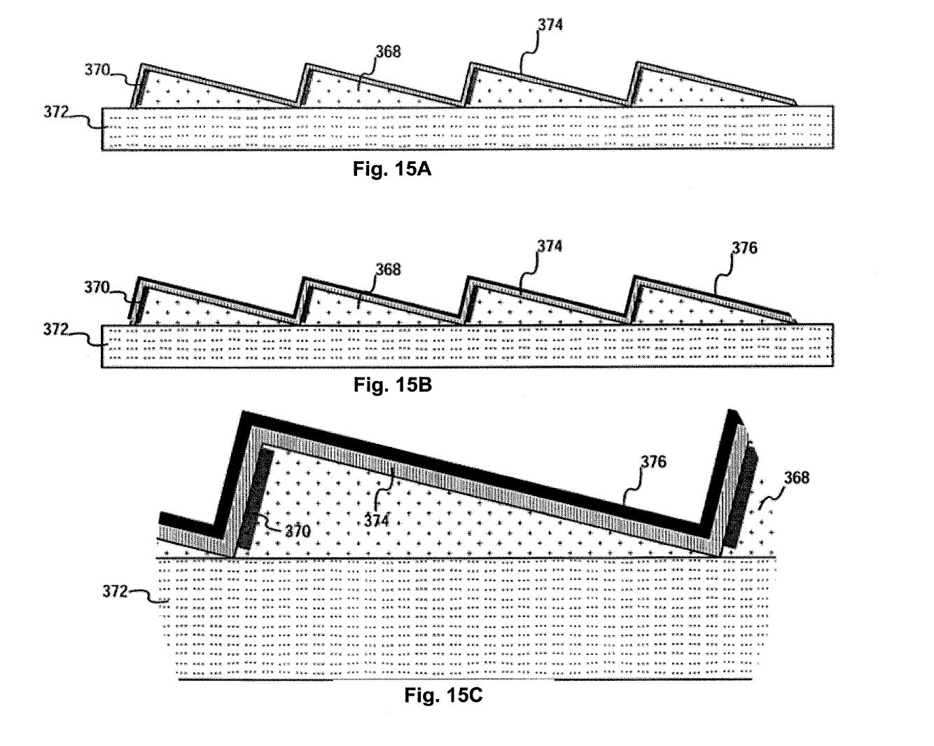

The PV cell strips 370 are partially encapsulated in the silicone forming the ridges, but their backside is revealed and can be encapsulated as well. As shown at FIG. 15A, a second layer of silicone 374 can be applied. This layer can be the same silicone as was used to make the ridges (prisms 304). It can also be a lower index silicone. If, for example, the ridges were made of silicone with an index of 1.5, the second layer of silicone 374 can be made out of a layer of silicone with an index lower than 1.5.

Silicones exist which have indexes of around 1.4, (for example, Sylgard™ 184 form Dow Corning has an index of refraction of 1.42) and these could be employed. Mixing 1.4-index silicone with 1.3-index fluorinated PMMA or some other similar material could achieve lower index materials.

The second layer of silicone encapsulant (374) can be added by a second moulding step using another mould, or by any other suitable technique such as, for example, spray painting. The silicone would have to be applied in very thin coats so that it would remain smooth and not run, however, it could be built up with a few coats.

Instead of a polished steel mould 366, an acrylic mould can be made to make the capture layer as shown at, for example, FIGS. 14A-14D. There are two advantages to using an acrylic mould. First, a cast could be made with which to build moulds and, thus, moulds would be inexpensive allowing for rapid ramp-up of production for very low cost. One master casting mould would be made (out of steel or glass) and acrylic moulds would be cast from this part. The second advantage, if silicone is used to make the ridges on the capture layer, is that acrylic does not bond very strongly to silicone. Because of this, the mould would be easy to remove. If the acrylic mould were very smooth, as would be the case if cast from a polished master casting mould, then the silicone ridges would also be very smooth. In addition to acrylic, other polymers and plastics could also be cast, or moulded, to manufacture moulds for making Capture Layer based solar modules. In addition to casting a whole mould out of acrylic, it could be built up from material including cast or extruded acrylic sheet.

FIGS. 15B and 15C show a mirror coating 376, which can be applied over the silicone layer 374 by a painting technique, or by using another technique such as sputtering. For example, an aluminum mirror can be applied. The final structure is the same as that shown at FIG. 13, with a capture layer and ridges made from moulded silicone and sheet glass. The lower index of refraction material encapsulates the cells and insulates them from the mirror. This is useful in case the mirror is made from a metal like aluminum that is electrically conductive.

Instead of a mirror, after a coat of lower index material 374 is added, the panels can be painted in any color. This will give the solar modules the appearance of any color from certain viewing angles, while being an effective solar panel for light incident from other angles.

FIGS. 14A-14D and 15A-15C showed four ridges only on a sheet of glass. In practice, any number of ridges can be used. The ridges could be on the order or 1 cm tall, and the glass sheets could be as large as available glass sheets are. Some exemplary sizes are 8 feet by 4 feet, 2.5 meters by 1.5 meters, etcetera. The ridges can have PV cell strips of 1 cm wide secured thereto, the PV cell strips being as long as the glass sheet. The PV cell strips would be made out of any number of individual PV cells.

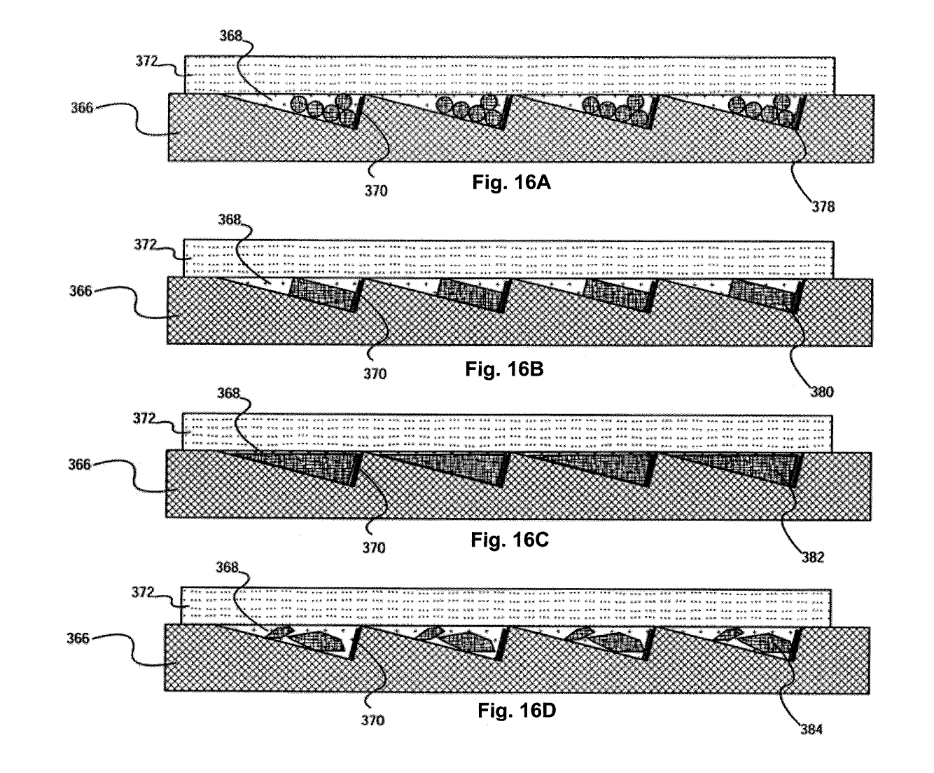

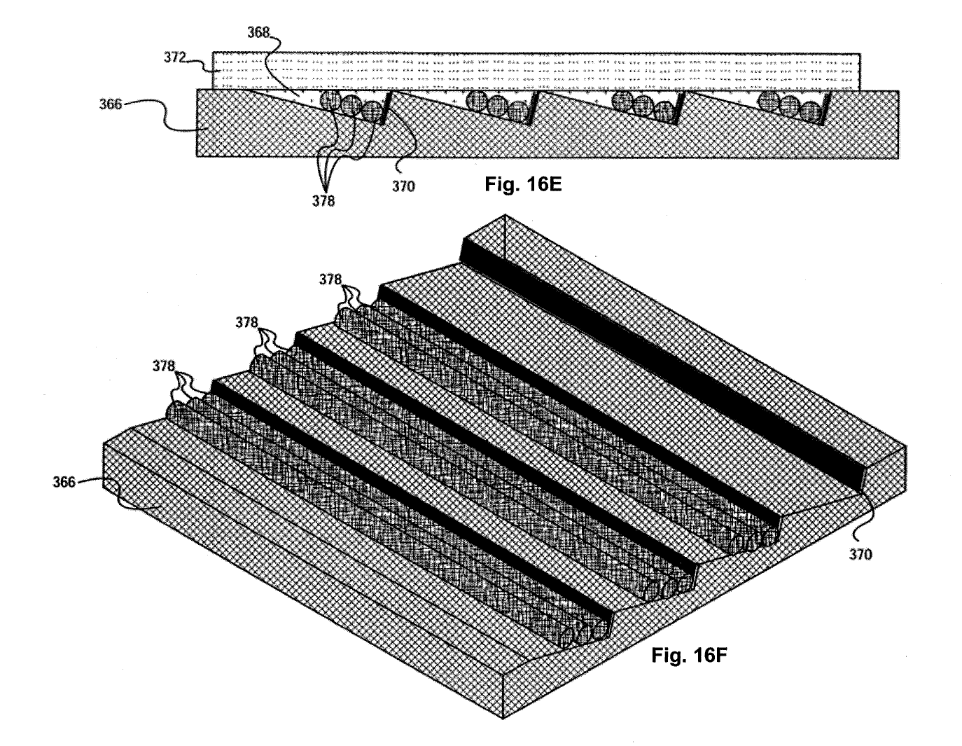

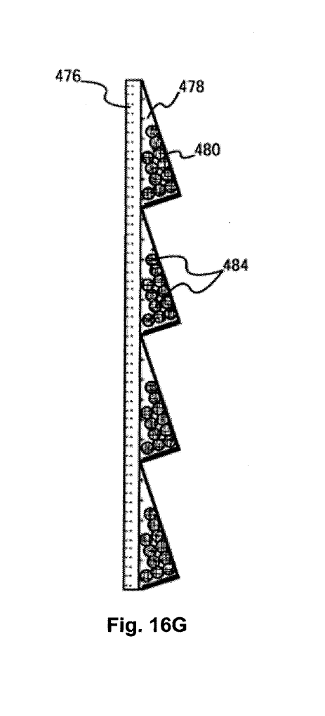

In order to utilize less silicone material, both because it can be costly and because it can take a long time to cure if its thickness is too great, glass filler material can be employed in making the prisms 304. Examples of this are shown at FIG. 16A-16F. The mould 366 is filled with a glass material 369, also referred to simply as a filler material, before being filled with silicone 368 and capped with a glass sheet 372. The glass material 369 can abut directly against the PV cells 370 to hold them in place in the mould 366. FIGS. 16A-16F show different geometries of glass material that can be used as filler. Some options include glass rods 378, glass sheet or blocks 380. Alternately, the mould could be almost completely filled with glass pieces 382 which are ridge shaped (wedge shaped) to fit the mould. Alternately, glass shards 384 could be used. Provided that the silicone 368 has a very closely matched in index with the glass then light will not be scattered and reflected at the interface between the glass pieces and the silicone, the two materials will makeup the ridges together. The silicone 368 is used to fill any interstices between the pieces of filler material, as well as to help fill the mould.

The glass sheet 372, silicone 368 and glass material filler can be selected such that their thermal expansion coefficients are suitably matched to each other. Further, in the case where the PV cells 370 are secured directly to a piece of glass filler material, such as shown at FIG. 16C where the PV cells 370 are secured directly to the glass wedges, the glass wedge can be chosen such that its thermal expansion coefficient is closely matched to that of the PV cells. Silicon PV cells have a coefficient of thermal expansion of 2.49 parts per million per degrees Kelvin at 20 degrees Celsius. Dow Corning Sylgard™ 184 has a coefficient of thermal expansion of 310 parts per million per degrees Kelvin at 20 degrees Celsius, other silicones by companies like Dow Corning, Quantum Silicones, and NuSil have expansions coefficients ranging between 220-360 parts per million per degrees Kelvin at 20 degrees Celsius. Glasses are much lower in thermal expansion, for example Borosilicate glass by Schott marketed under the name Duran™ has a coefficient of thermal expansion of 3.3 parts per million per degrees Kelvin at 20 degrees Celsius, other borosilicate glasses by companies like Corning and SIMAX have similar characteristics and are very closely matched to silicon PV cells. Fused Silica has lower coefficient of thermal expansion of 0.55 parts per million per degrees Kelvin at 20 degrees Celsius, while soda-lime glass typically has coefficients of thermal expansion greater than 8 parts per million per degrees Kelvin at 20 degrees Celsius. The main glass being considered for use as both the window panes and the glass filler material are borosilicate glasses.

Other options of glass material 369 include glass fibers, glass beads, or glass in any other suitable shape. FIG. 16E shows glass rods 378 used as filler material. FIG. 16F shows the same rods 378 in a mould 366 before silicone has been added. The glass rods hold the PV cells inside the mould before silicone is added.

It was described, in relation to FIGS. 16A-16F, that the prisms could be glass filled using either rods or other glass shapes that are index matched to silicone that makes up the primary material of the ridges of the capture layer. While it is possible to find glass and silicone that are very closely matched in terms of index of refraction, small deviations are almost inevitable. By way of example, consider the capture layer based solar module, with glass insert rods as shown at FIG. 16G. The glass sheet 476 and the ridges 478 of silicone have an index of 1.48. There is a mirror 480 separated from the ridges by a low index cladding (not shown), where the low index cladding has an index of 1.3. The filling rods 484 have an index of refraction of 1.52. The effects of this mismatch are to scatter some of the light by Fresnel reflections at the many interfaces between the silicone and the glass filler (if the indices were identical no scatter due to Fresnel reflections at the interfaces could occur). In the example shown, there are few enough interfaces that no measurable loss will occur.

In fact, with an index variation of only 0.04 (1.52−1.48=0.04), only 0.02% of all incident light will be reflected at each interface. Assuming that any Fresnel reflected light is lost (this is a pessimistic case because some light will be scattered but recaptured by the capture layer) then a simple formula may be determined. For N interfaces, the transmission T efficiency will be equal to:

T=99.98%^{N}

After 100 interfaces (light leaving the silicone and entering the rod or visa versa) the transmission efficiency only drops to 98%. After 1000 interfaces however, the transmission efficiency drops to 82%. It is clear from this that using fine ground glass as filler is not advisable, because that would introduce many thousands of interfaces along the path length of the light to the PV cell. However, using 100 very fine glass fibers to fill each channel would be appropriate and a small index mismatch would be allowable.

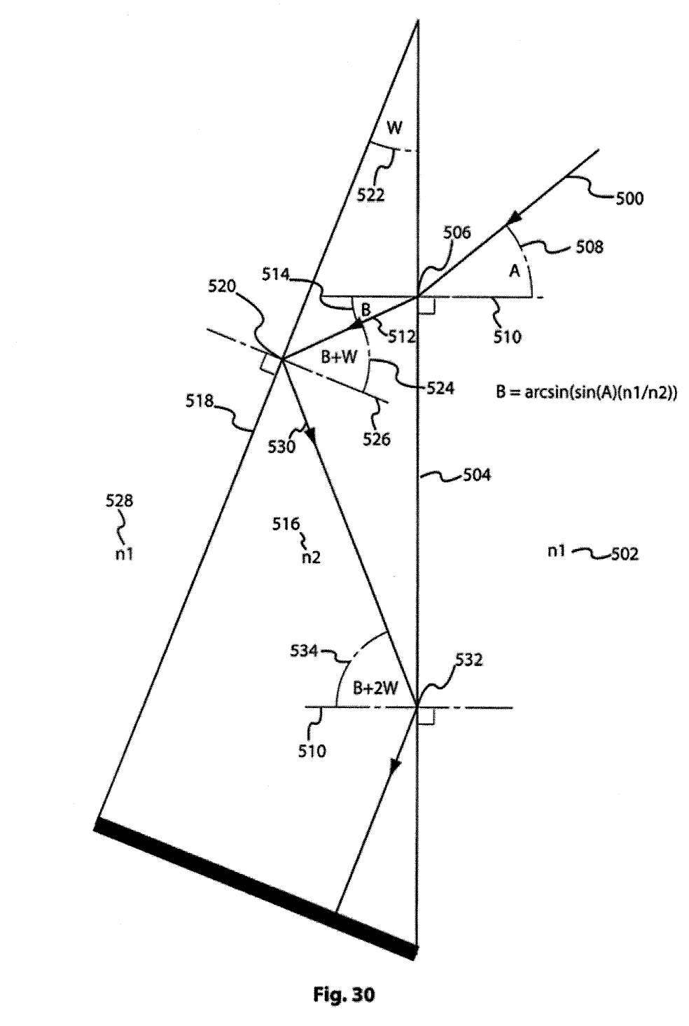

It is simpler to find high index glass fibers than it is to find high index silicone, one can use higher index fibers than silicone. For example, if the ridges 478 in FIG. 30 were made using Sylgard™ 184 from Dow Corning with an index of 1.42, and glass rods 484 have an index of 1.42 the critical capture angle is around 12 degrees. If the rods 484 shown had an index of 1.52 then the critical capture angle is reduced to 10 degrees. Using slightly higher index glass filler can be advantageous because it reduces the critical capture angle. However, if one goes too far then the Fresnel back reflections at interfaces can become problematic.

Using fine glass fibers (0.1 millimeter to 3 millimeters) in diameter is an appropriate size for the application of filling the ridges. They are inexpensive, readily available, and will help strengthen the silicone ridge almost like fiberglass. It will also offer a considerable cost savings versus creating a ridge using pure silicone, which can be expensive. The size of the glass fibers will likely be smaller than what has been shown in this document, but not so small that the number of interfaces introduced in the path of light on the way to the PV cell becomes in the thousands. Beads can also be used to fill the ridges, and may be employed, but fibers have the added benefit of reinforcing the ridge.

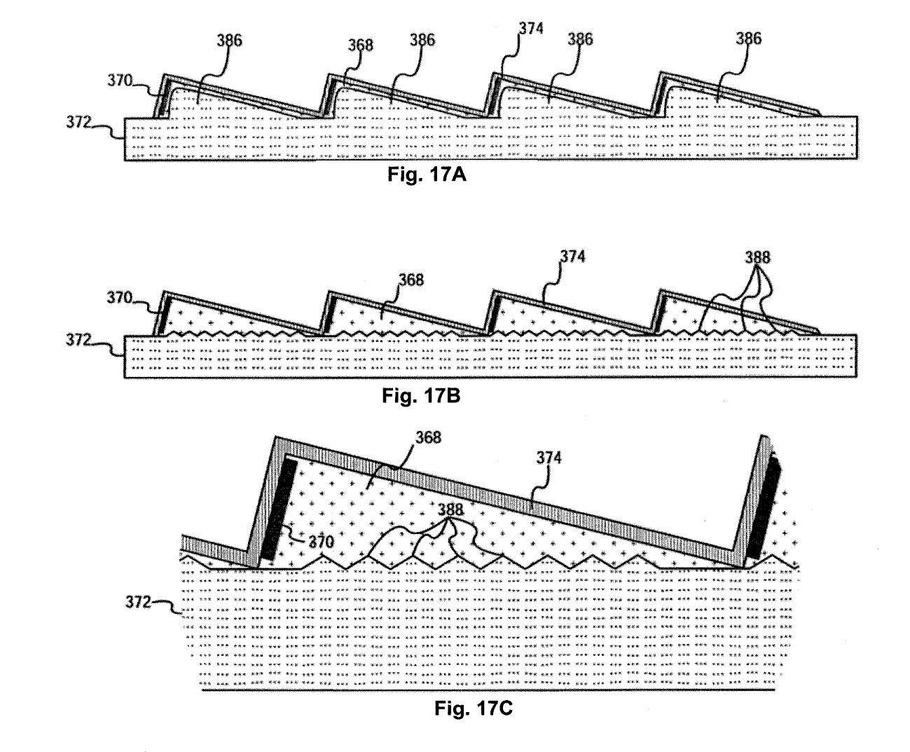

As shown at FIGS. 17A-17C, in further embodiments, the glass sheet 372 can be textured instead of flat. FIG. 17A shows this can be done so that the glass sheet fills the mould almost completely. The glass sheet 372 has integral ridges 386. Silicone with the same index as the glass sheet 368 can be used to encapsulate the PV cells 370. In the embodiment of FIGS. 17B and 17C, a glass sheet 372 with integral small ridges 388. These ridges 388 increase the surface area of contact between the glass sheet 372 and the silicone 368 that forms the ridges. A second layer of silicone 374 is also added on top of the ridges as before to completely encapsulate the PV cells 370. This second layer of silicone 374 should be of lower index than the primary silicone 368 that forms the ridges, which has the same index as the glass sheet 372. After the second lower index film of silicone 374, a mirror coat or a paint coat for color can be added (these are not shown).

Also, as will be understood by the skilled worker, it is possible to combine textured glass sheets with glass filler material, so that small ridges 388 could be used in conjunction with, for example, glass fibers and silicone to form the ridges on the capture layer.

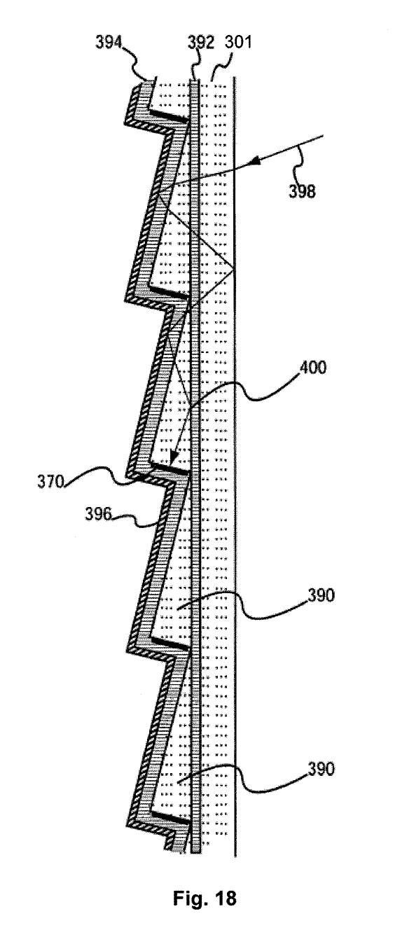

In another embodiment shown at FIG. 18, a low index layer of material can be used to separate the glass sheet from the prisms of the capture layer. A glass sheet 301 is separated from the ridges 390 by a layer of low index material 392. A same or similar low index material 394 separates the prisms 390 (ridges) from the mirror layer 396. An exemplary ray 398 is shown. It follows a virtually identical trajectory to the ray 342 from FIG. 13, except that it totally internally reflects at a point 400 on the interface between the ridge material 390 and the low index material 392. As will be understood by the skilled worker, similar to examples described above, instead of a mirror, a layer of paint or a colored plastic or polymer can be used.

Instead of a mirror 396 backing made using a metallic mirror, a multi-layered dielectric mirror could be employed. These have several advantages. First, they can be made more efficient for target wavelengths than metallic mirrors. Second, they can be largely transparent to unwanted wavelengths of light, such as far infrared light that would heat up a PV cell without producing electricity. Thirdly, they can appear transparent for certain angles while reflecting for other angles.

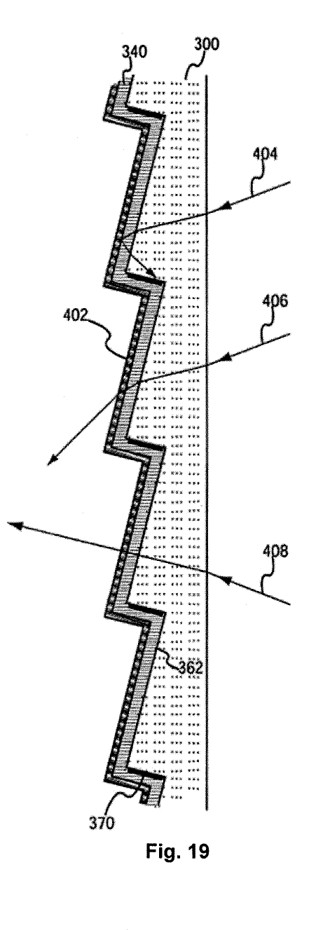

Dielectric mirrors can be designed for particular angles of incidence and wavelength. If silicon PV cells are used, then any light with a wavelength greater than about 1100 nm will not produce electricity and therefore it is not necessary that it be reflected towards a PV cell. Further, any light that is coming from a viewing angle, such as from below on a vertically mounted solar panel, could be allowed to pass. FIG. 19 shows a panel made using a dielectric mirror 402. Useful light 404 is captured, but infrared light 406 is passed through the panel. This is sometimes called a cold mirror, because it does not reflect infrared light. Light form viewing angles such as that of ray 408 are also not reflected by the dielectric mirror.

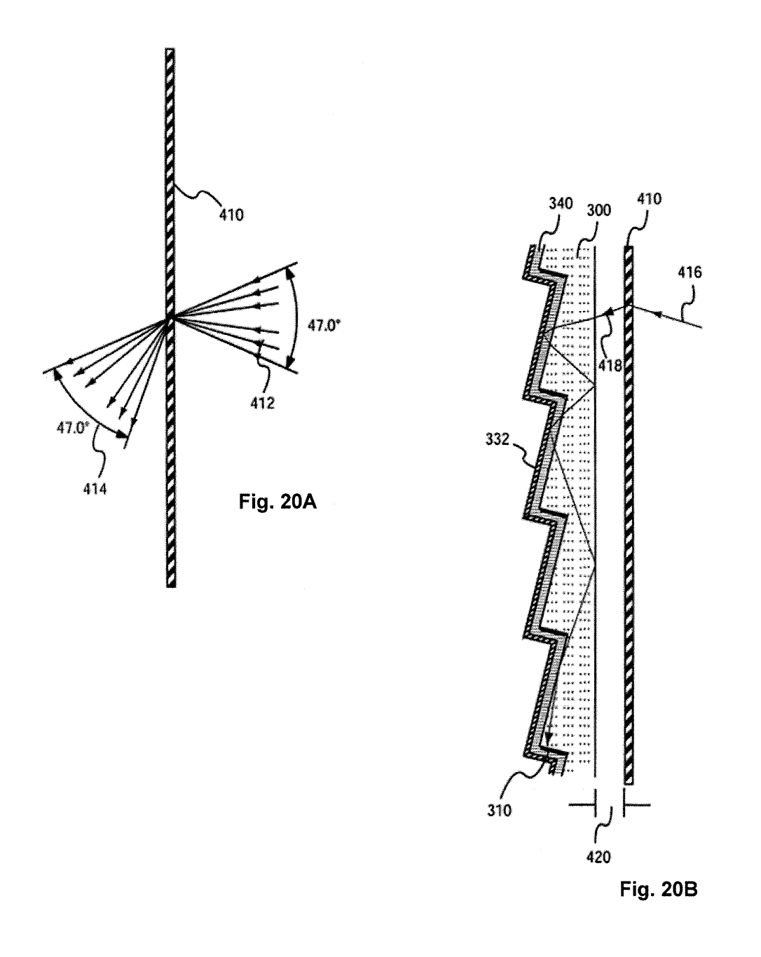

It is possible to use holographic deflectors made using volume phase holography, or to use a deflector made using a diffraction grating, in order to alter the effective capture angle of a capture layer. FIGS. 20A and 20B shows examples of the kinds of holograms that can be employed in the present invention. FIG. 20A shows a transmissive hologram 410, which deflects incident light from inside an angle of incidence inside a cone 412 into an output cone of angles 414.

As shown at FIG. 20B, when the hologram 410 is placed in front of a capture layer 300 it deflects incident light 416 so that it is captured as shown in FIG. 20b. The output ray of the hologram 418 has been deflected so that it is now at or above the critical capture angle of the capture layer. At FIG. 20B, there is shown a layer of low index material 340 and a mirror 332 on the capture layer 300. Light is captured and propagates to a PV cell 310. There is an air gap 420 between the capture layer 300 and the deflecting hologram 410. This air gap could also be filled with a low index material, for example, the same material used to fill the area 340 between the capture layer 300 and the mirror 332.

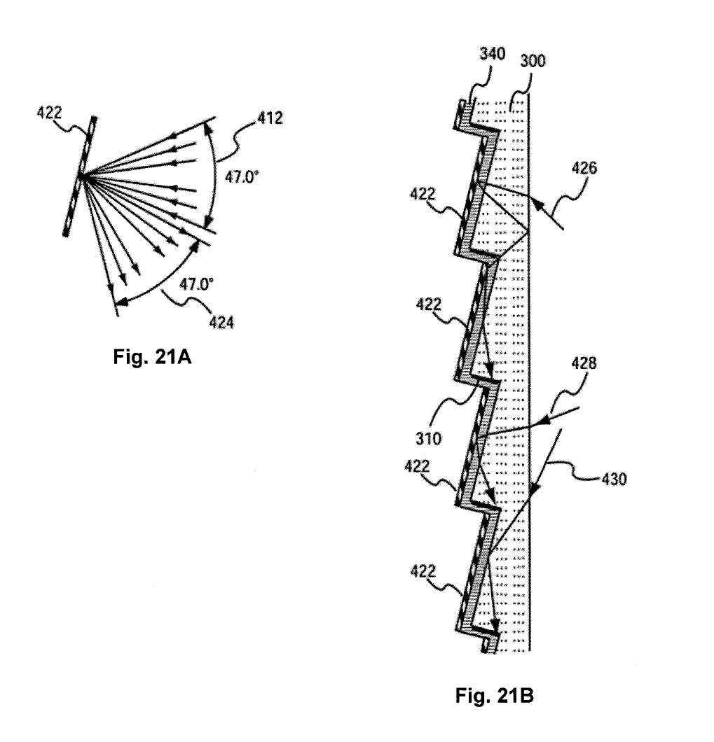

Another embodiment of the present invention is shown at FIGS. 21A and 21B where a deflecting holographic reflector 422 is shown. The holographic reflector 422 reflects and deflects light from within an incident cone of angles 412 into an output cone of angles 424. The holographic reflector 422 can replace the mirror 332 or the dielectric mirror 402 shown in exemplary embodiments above. The holographic reflector 422 enables the capture of incident light from lower critical angles such as, the light ray 426 of FIG. 21B. The holographic reflector 422 can be separated from the capture layer 300 by an air gap, or by a layer of lower index of refraction material such as the layer 340 shown. Some incident light, such as light ray 426 will reflect twice off the holographic reflector. Other rays, such as 428 will reflect only once off the holographic reflector. Some other rays, such as 430, will only reflect off the interface (that is, off the reflector face) between the capture layer 300 and the lower index material 340 (the material in 340 can be air as well, which is also of a lower index than the capture layer).

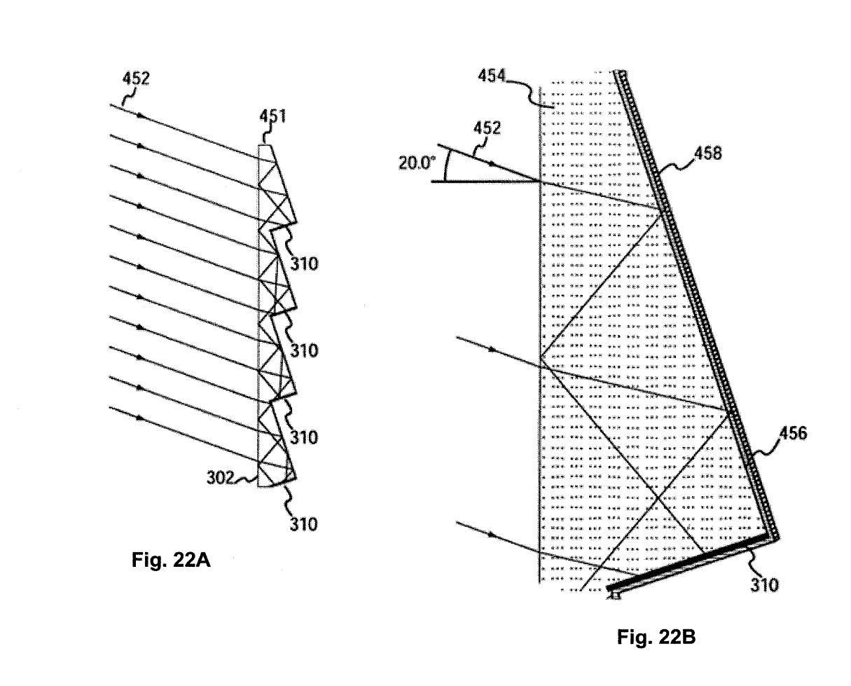

FIG. 22A shows an example of a capture layer based solar module 451 with 3.2 times concentration (the outside face 302 has 3.2 times more area than the sum of the areas of PV cells 310). Incident light 452, in this case 20 degrees from the normal of the panel, is captured and propagated to the PV cells. FIG. 22B shows detail on one ridge of the capture layer. There are three materials, material 454 has an index of refraction of 1.5 and is comprised for example, of glass or glass with silicone ridges. The ridges can be glass filled, as was described above in relation to FIGS. 16A-16F and 17A-17C. There is a low index material 456 with index 1.4. This could be, for example, Sylgard™ 184 from Dow Corning (which has an index of 1.42) or any other appropriate material. There is also a conformal mirror 458. A majority of rays above the critical capture angle (about 10 degrees in this design) are captured and conducted to PV cells.

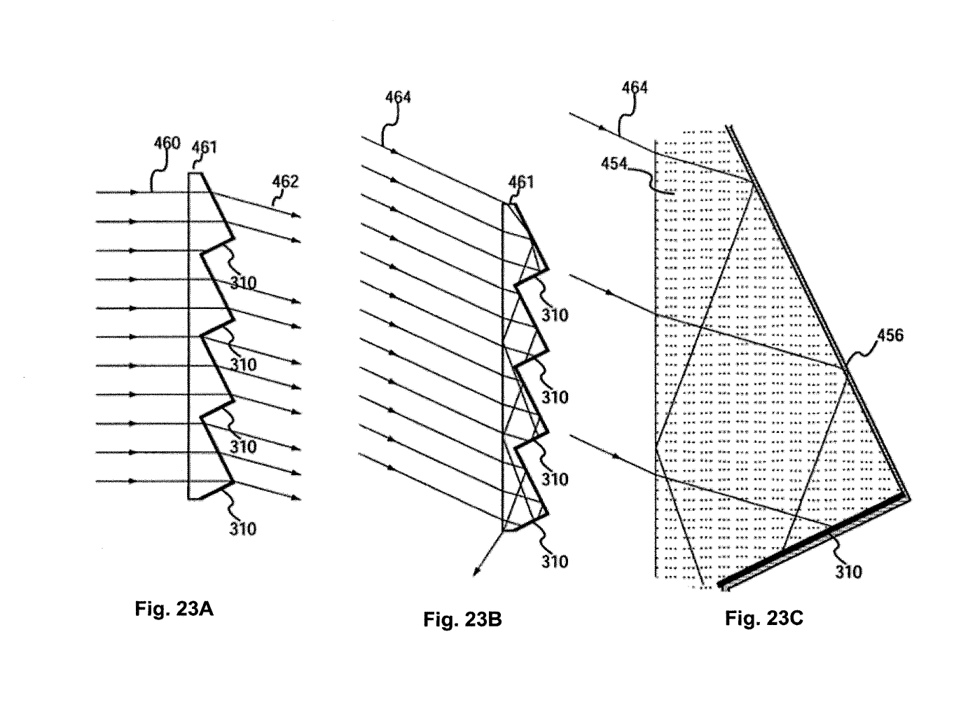

FIGS. 23A-23C show a capture layer based solar module 461 with 2.3 times concentration. There is no mirror backing. Instead, as shown in detail in FIG. 23C there are two materials. The material 454 has an index of refraction of 1.5 and is comprised of glass or glass with silicone ridges. The ridges can be glass filled, as was described above in relation to FIGS. 16A-16F and 17A-17C. There is a low index material 456 with index 1.4 that serves as a cladding. As shown in FIG. 23A, normal light 460 is deflected by the capture layer and exits 462. Light above the critical capture angle, such as 464 at FIGS. 23B and 23C is captured and propagated to the PV cells 310.

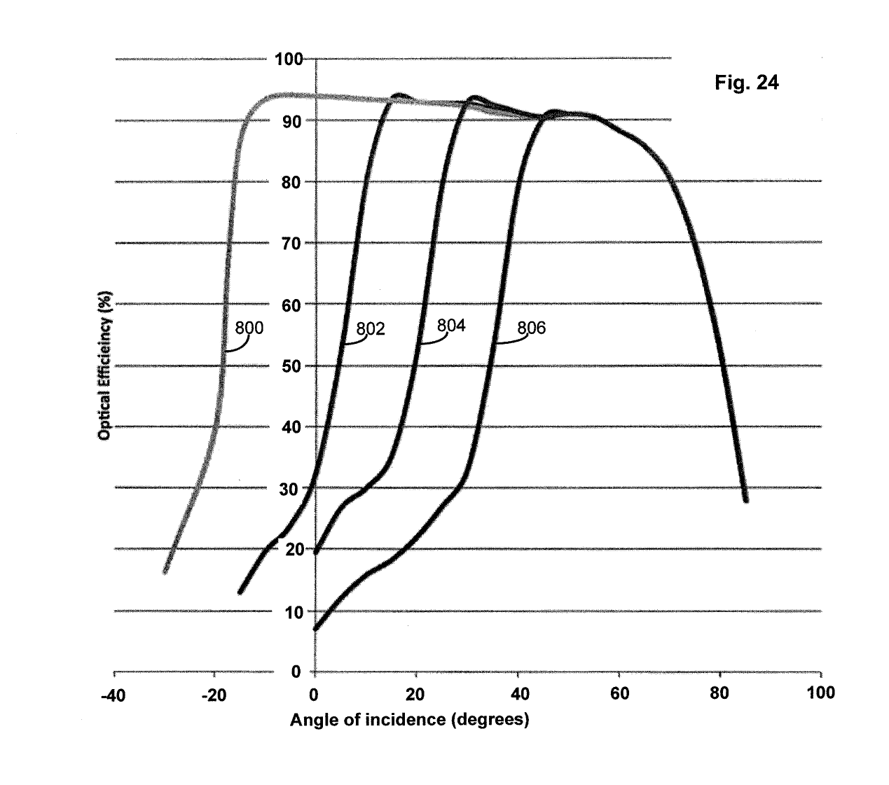

FIG. 24 shows a graph with four plots that show the simulated efficiency of each of the designs described above in relation to FIGS. 22A, 22B, and 23A-23C, both with and without mirror coatings. Plot 800 corresponds to a 2.3× concentrator with mirror; plot 802 corresponds to a 2.3× concentrator without mirror; plot 804 corresponds to a 3.2× concentrator with mirror; and plot 806 corresponds to a 3.2× concentrator without mirror. The critical capture angle is clearly noticeable in the graph: as the optical efficiency (the efficiency with which light is conducted to the PV cells) increases sharply above a particular angle for each version of the solar module. Adding a mirror behind the low index cladding dramatically reduces the critical capture angle. In the case of 2.3 suns concentration with a mirror the critical capture angle is reduced to below normal incidence. Clear modules have higher critical capture angles. Not shown in this graph are variants using holographic reflectors, which would have lower critical angles.

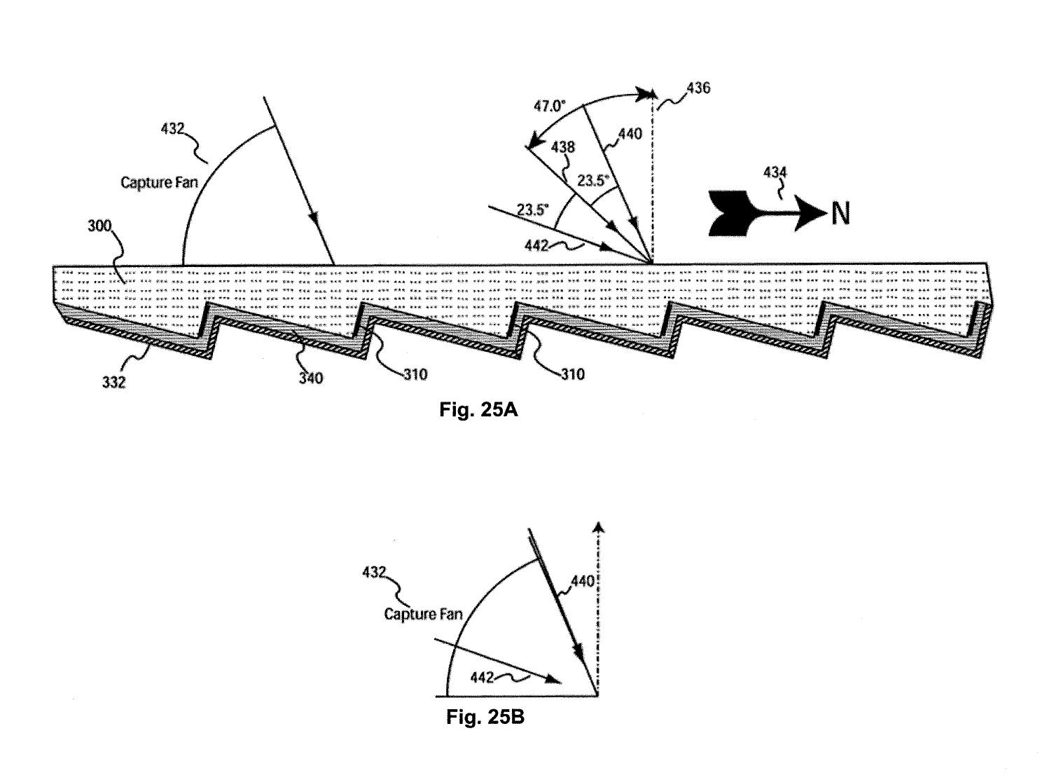

The solar panel windows and solar panel walls exemplary embodiments described above have been drawn vertically, and have been described as solar walls and windows. However, they can also be used as solar skylights and solar roofing material. Solar panels using capture layers can be used in rooftop applications without any lifts to orient the panel. An example of such a solar panel is shown at FIG. 25A with a capture layer 300 having a refractive index of 1.5, a low index layer 340 having an index below 1.5, and a mirror 332 to capture and couple light to several PV cells 310. Any light incident from an angle inside the capture fan 432 will be coupled to the PV cells. In the example drawn, the capture fan extends downs to 22.5 degrees to the south of normal, using the North arrow 434 from the figure as a reference.

The angle of incidence of sunlight on a flat surface depends on the latitude of the surface and the time of the year. It will vary over a fan of incident angles centered on the latitude and measured from the surface normal of a flat surface 436. As an example, if the latitude is 47 degrees north, the center of the fan of incident sunlight will be at 47 degrees south of the surface normal as indicated with the arrow 438. The sunlight will be incident at this angle at noon during the equinoxes. During the summer solstice, the sun will rise to its maximum height in the sky, and conversely its minimum angle with respect to the surface normal 436. The summer solstice brings the incident light 23.5 degrees closer to the normal, and the angle of incidence is shown with the arrow 440. During the winter solstice, sunlight drops low in the sky and its angle of incidence is indicated by the arrow 442. During all other times of the year, at noon, sunlight is incident between the extreme angles shown by the arrows 440 and 442. FIG. 25B shows an overlap between the capture fan 432 of the solar panel and the extreme angle of incidence of sunlight 440 and 442. As is clear, all the incident sunlight has an angle of incidence inside the fan of angles that are captured by the panel. Thus the panel of FIG. 25A would work at any latitude above 47 degrees North and would capture all the sunlight all year round without lifts. It would also work if oriented the opposite way south of 47 degrees South.

To make modules for use closer to the equator, as an example, holographic mirrors or deflecting layers can be employed as described above, or the concentration can be reduced, for example, by changing the length ratio of the reflective face to that of the collector face, to lower the critical capture angle.

Up until this point, low index material (with an index of around 1.3 or 1.4 but in any case less than 1.5) has been employed in order to separate the higher index material of the capture layer (index of approximately 1.5) from a mirror coating, either a metallic or multi-layered dielectric, a holographic film, or paint. However, even if there is no final coating, or if the final coating is a clear material, it can be useful to have a low index material on the backside of the capture layer. The reason for this is that the low index material serves as a cladding (also referred to as a protective cladding). A cladding allows for total internal reflection to occur at the interface between the high index material and the low index material. In this way, if dust or dirt builds up on the backside of the module, it will have far less of a detrimental effect to performance if there is a cladding than if there is not.

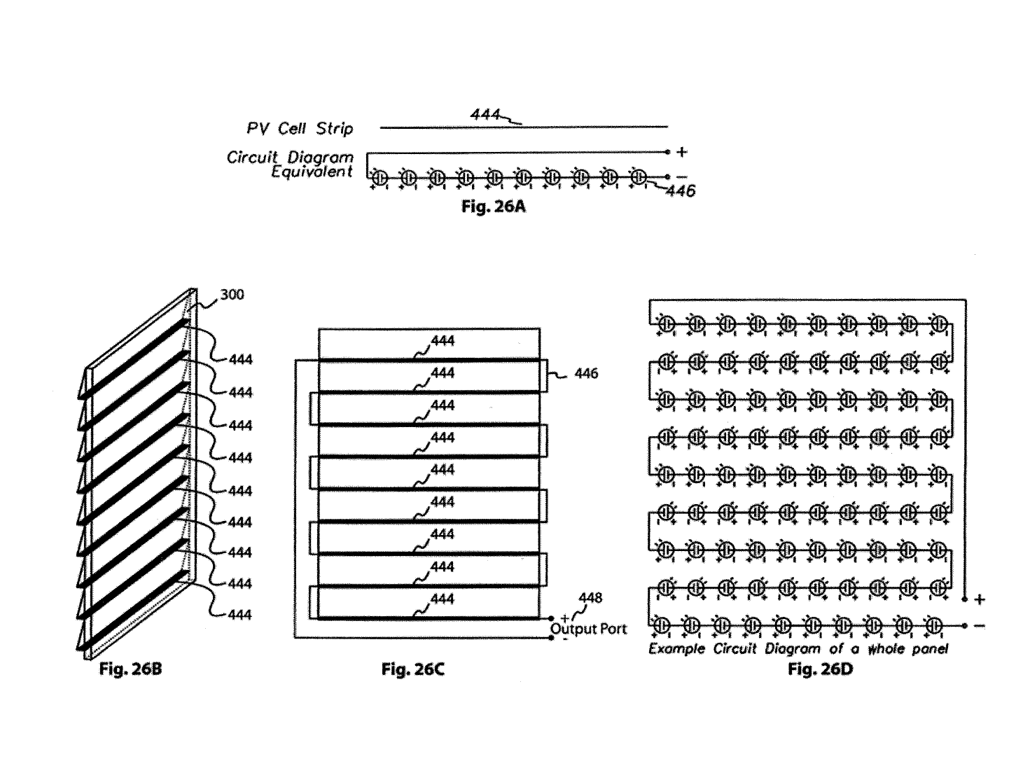

All the exemplary modules described above, whether solar window modules with a rectifying layer or mirror backed module or some sort, uses PV cell strips. An example of these PV cell strips is shown at FIG. 26A. In the present example, each PV cell strip 444 includes a string of series connected individual PV cells, shown in circuit diagram notation. FIG. 26B shows strings 444 affixed to the ridges of the capture layer 300. FIG. 26C shows how these individual strings 444 are wired together in series 446. Each module has one output port 448 with a positive and a negative lead. FIG. 26D shows an example of a whole panel circuit diagram, showing each cell as an individual unit. The module shown has 90 cells, but modules with any suitable number of PV cells can be made. As will be understood by the skilled worker, blocking diodes or bypass diodes can be added to the circuit as is typically done with solar panels.

PV cells are typically wired in series to make solar panels with silicon PV cells, so wiring the PV cell strips in series could use the same basic techniques such as solder ribbon.

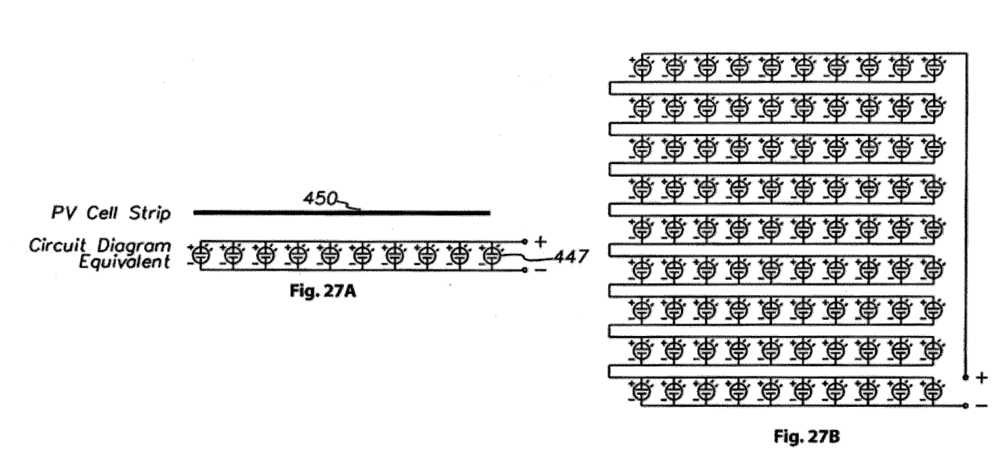

Another way to wire the PV cell strips is in parallel, as shown in the example of FIG. 27A. Each string 450 is made up of a number of parallel-connected cells 447, and then the strings are connected in series as shown in FIG. 27B to make a module. The advantage of this arrangement is that the strings 450 in effect act like one large PV cell. If a cell breaks for whatever reason, the remainder of the PV cells continues to function and produce current and the circuit is not broken. If all the cells were connected in series and one cell broke in half that would create an open circuit.

It is desirable to have a wiring scheme that is robust against cell breakage considering that the cell strips can be long and thin. If all the cells are in series in each PV cells strip as in FIG. 26D, then a failure that caused a single cell to short circuit would short out the whole strip to become inactive. However, because PV cell and wiring failures are more likely to lead to open circuits, the parallel mode of deployment is more robust.

The present disclosure also has applications in electronic billboards (typically large outdoor screens). Such electronic billboards can be made with a clear solar panel having a capture layer as described above, for example, in relation to FIGS. 23A-23C. Most electronic billboards employ bulbs (or other types of illumination devices) that cast light isometrically in all directions. The viewers of the billboards, being on foot or in cars, are generally below the billboards. Therefore, it would be advantageous to devise an optical system that deflects light downwards; this would increase the efficiency of the electronic billboard by shinning more light in the direction of the viewers.

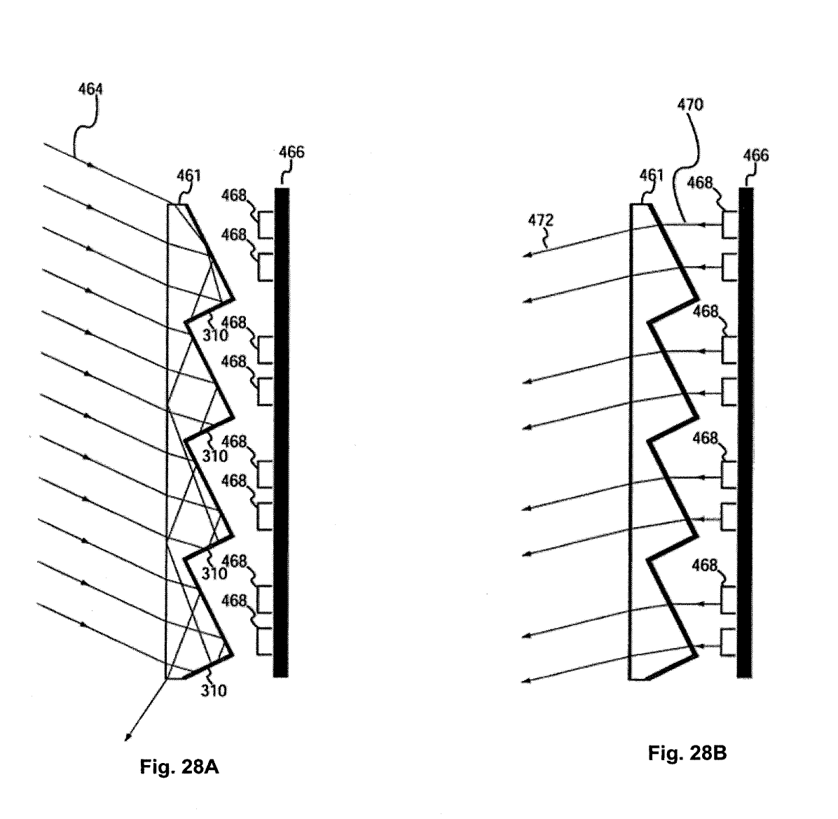

FIG. 28A shows a very simplified electronic billboard 466 with eight pixels 468. In front of the billboard is a capture layer based solar module 461 such as from FIG. 26A-26C. Incident light from above the critical capture angle 452 is coupled to PV cells 310 and converted to electricity. As shown at FIG. 28B, the capture layer based solar module 461 deflects light emitted from the pixels 470 of the billboard 466 downward. The final output light 472 is traveling in a downwards direction, towards potential viewers, rather than off into space where no one will see it. By redirecting the light down towards viewers, the billboard can deliver more watts of light to viewers with pixels of less brightness. This allows for less energy to be employed for an image of the same brightness.

The same optics achieves this down deflection as are used to capture light energy from the sun. A digital billboard which use less power and which also produces electricity by coupling its output optics with solar cells would be a very desirable product.

In FIGS. 28A and 28B, there are only eight pixels 468 and four ridges (prisms) on the capture layer based solar module 461. However, there can be any number of pixels on the digital billboard, and any suitable number of ridges on the capture layer based solar module. Several separate modules could be built in front of a single large screen if the area to cover were very large.

In the present disclosure, the figures have been simplified in order to make them easier to understand. In actual fact, even though one could, one would almost never make a capture layer based solar module, either a window with a rectifying layer, or a panel employing a mirror, or a Capture Layer acting alone, with only four ridges as shown in the majority of these patent drawings. Instead, one would likely make a very large solar module including numerous ridges.

An example of sizes for real world applications is given below for the design from FIGS. 22A and 22B. A real module can employ, by way of an example only, a glass sheet of 8 feet by 4 feet, with silicone ridges 1 cm tall and 4 feet long and PV cell strips approximately 1 cm wide and 4 feet long. The ridge height would be 3.2 cm, so there would be seventy-six (76) ridges over the 8-foot height of the glass window. Each of these ridges would have a PV cells strip which would be itself composed of ten 120 mm long, 1 cm tall PV cells which would be wired in parallel, or in series, together inside the strip 4 feet long. The strips themselves would be wired together either all in series, or some combination of series and parallel. Bypass and blocking diodes can be employed in the wiring of the module. The voltage of silicon PV cells is approximately 0.45 volts, if all 76 PV cell strips were wired in series the module would have a final voltage of approximately 34 volts.

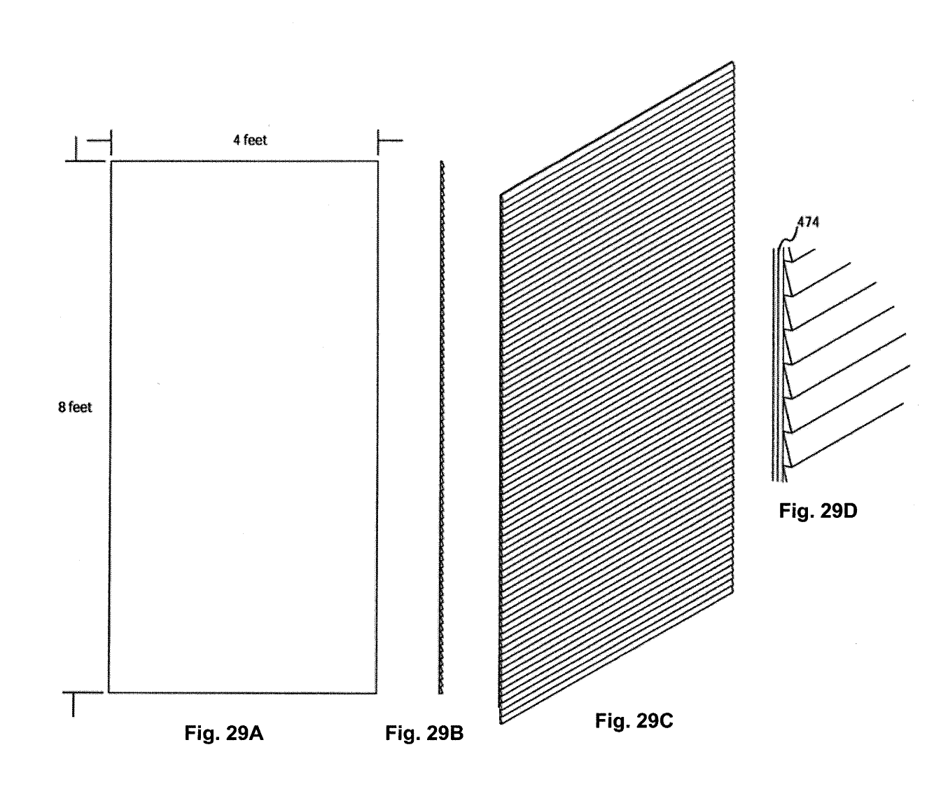

FIGS. 29A-29D show an embodiment of such an exemplary panel. FIG. 29A shows a front view of the panel, FIG. 29B shows a side view, FIG. 29C shows an isometric view showing the ridges, and FIG. 29D shows detail on the ridges (prisms) themselves. A glass flange 474 is visible in the detailed view FIG. 29D. It is likely, given the molding method employed where a glass sheet is used to close the mould that the glass sheet would extend beyond the edges of the ridges themselves. Not shown in FIGS. 29A-29D are the PV cells, the cladding coat of lower index material, or the mirror coating, nor the glass filler that can be inside the prisms. FIGS. 29A-29D are shown purely to give a sense of scale and not to limit in any way the present disclosure.

The capture angle of a capture prism depends on the index of refraction of the capture prism and surrounding media and its wedge angle and can be calculated as follows. Consider the system shown in FIG. 30. An incident beam of light 500 in a medium with an index of refraction of n1 502 is incident upon a collector outside face 504 at a point 506. The ray makes an angle A 508 with the surface normal 510 of the outside face 504. The ray will deflect on entry into the prism, and the deflected ray 512 will make an angle B 514 with the surface normal 510 depending. The angle B 514 depends on the index of refraction n2 516 inside the prism, the index n1 on the other side of the collector 504, and the angle of incidence A 508 and is calculated according to Snell's law:

n1 sin(A)=n2 sin(B)

B=arcsin(sin(A)*n1/n2))

The ray 512 will strike the rear side (reflective surface) of the prism at a point 520. Given a wedge angle W 522 of the prism, the ray 512 will make an angle of B+W 524 with respect to the surface normal 526 of the rear side 518. The interface 518 separates the material 516 with index of n2 from the material 528 with index of n1. If the angle B+W 524 is greater than the critical angle for this interface, total internal reflection will occur. The critical angle for this interface can be calculated as:

Critical Angle=arcsin(n1/n2)

If the material 516 is glass and n2=1.5 and the material 528 is air, such as the air gap between the capture layer and the rectifying layer so that n1=1.0, then the critical angle is 41.81 degrees. If total internal reflection occurs then the ray is trapped indefinitely at this point. For a window where no mirror coating is applied, and where the surrounding media n1 is air, then the critical capture angle can be calculated using:

B+W=arcsin(n1/n2)

arcsin(sin(A)(n1/n2))+W=arcsin(n1/n2)

sin(A)(n1/n2)+sin(W)=n1/n2

sin(A)=1−sin(W)*n2/n1

A=arcsin(1−sin(W)*n2/n1)

For example, if W=20 degrees and n1=1.0 and n2=1.5 then A=29 degrees. Any ray at an angle of incidence higher than the critical angle will also be captured.

If the material 528 has an index of refraction of n3 instead of n1, it can be shown that the critical capture angle A=arcsin(n3/n1−sin(W)*n2/n1).

If the angle B+W 524 is less than the critical angle then reflection will not occur unless a mirror is applied to the backside of the ridge 518 or if a mirror is placed parallel to the face 518 such as when a mirror coating is applied to the rectifying layer, as shown above at FIG. 13. In this case the ray is reflected and the reflected ray 530 will strike the collector face 504 at a point 532. The angle that the ray 530 makes with the surface normal 510 is B+2W 534. If total internal reflection occurs then the ray is trapped indefinitely at this point. The critical capture angle for rays when a mirror coating is present, which can be referred to in the present disclosure as a second critical capture angle, will always be lower than the critical capture angle for rays with no mirror coating. It can be calculated in the same manner as above.

B+2W=arcsin(n1/n2)

arcsin(sin(A)(n1/n2))+2W=arcsin(n1/n2)

sin(A)(n1/n2)+sin(2W)=n1/n2

A=arcsin(1−sin(2W)*n2/n1)

For example, if W=20 degrees and n1=1.0 and n2=1.5 and a mirror is present at the face 518 then A=21 degrees. Any ray at an angle of incidence higher than the critical angle will also be captured.

If the material 528 has an index of refraction of n3 instead of n1, it can be shown that the critical capture angle A=arcsin(n3/n1−sin(2W)*n2/n1).

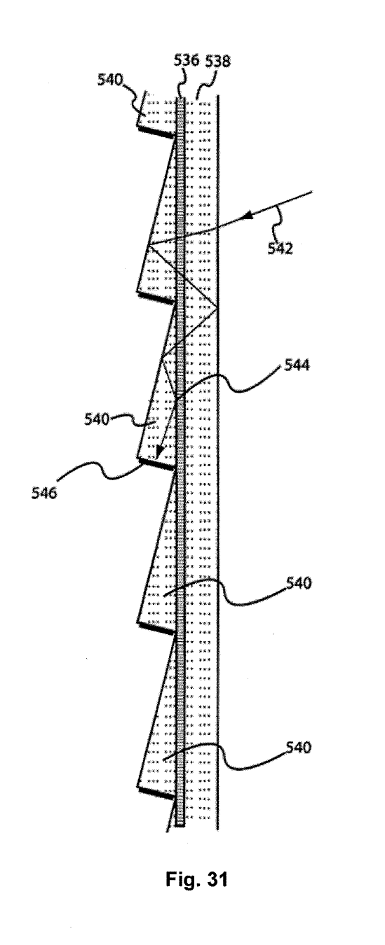

FIG. 31 shows a similar embodiment as FIG. 18 except without a mirror backing. A low index layer of material 536 can be used to separate the glass sheet 538 from the ridges 540 of the capture layer. An exemplary ray 542 is shown. It follows a virtually identical trajectory to the rays shown before, except that it totally internally reflects at a point 544 on the interface between the ridge material 540 and the low index material 536. This reduces the total path-length that a ray will propagate before striking a photovoltaic cell 546. A reduced path-length will reduce attenuation due to absorption in the bulk material. It also reduces the amount of light that travels in the sheet, and this would reduce and make redundant a PV cell 1014 at the bottom of the capture layer as shown in FIG. 6. It also reduces somewhat the phenomenon of top photovoltaic cell skipping that is described below.

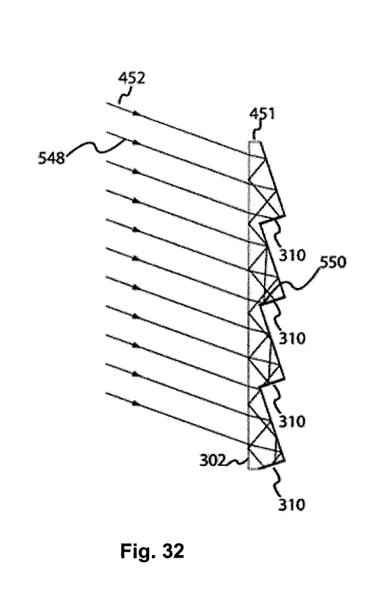

Consider FIG. 32, which is a reproduction of FIG. 22A with extra annotation. There are eleven rays drawn in the incident rays 452 and there are four photovoltaic cells 310. The eleven rays drawn are evenly distributed across the front collector face 302 of the capture layer. Only two rays strike the topmost photovoltaic cell with three rays striking each of the other photovoltaic cells. It is generally the case with this system than fewer rays will strike the top few photovoltaic cell strips than subsequent cell strips. This phenomenon is referred to as top photovoltaic cell skipping. The ray 548 is shown to skip the top photovoltaic cell; it is absorbed by the second photovoltaic cell from the top at the point 550. This sort of top photovoltaic cell skipping will occur in exemplary embodiments described above. If the system is wired using series connected photovoltaic cells as shown in FIG. 26C, then the top photovoltaic cell skipping will hurt performance significantly. Even if another series connection method is employed, current produced by the module will be significantly reduced. The reason is that each photovoltaic cell, assuming that they are the same size, will produce electric current proportional to the amount of light that strikes it. Therefore, if one has two cells, and one cell receives two-thirds the light of the other cell, as is the case with FIG. 32, it will produce two-thirds the current. If the photovoltaic cells are connected in series then the current by the cell producing two-thirds the current will limit the current that can be produced by the other cell. The cell receiving the least light is the cell that limits the current.

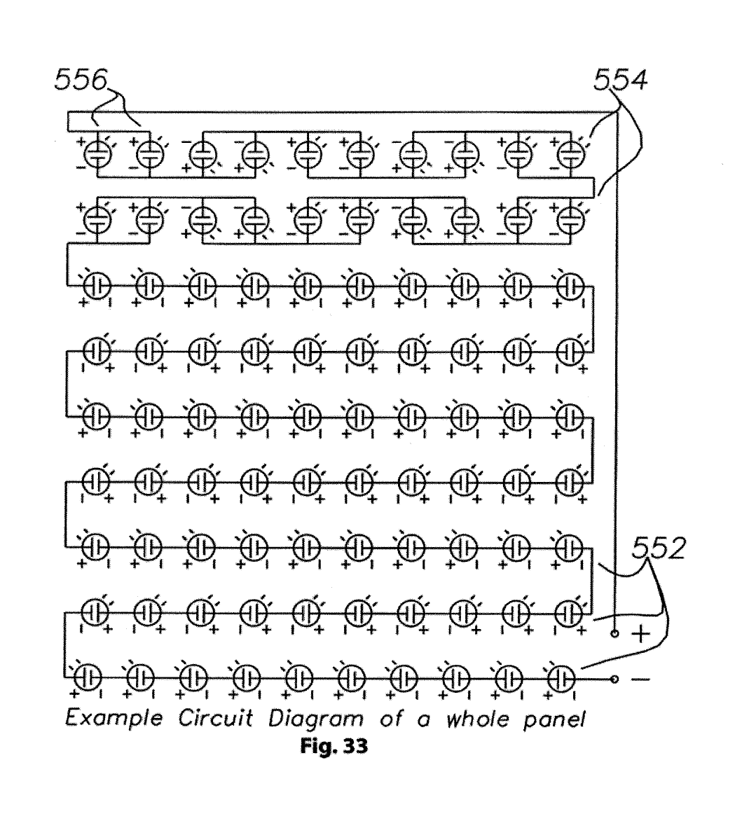

In the case of a capture layer, the first and perhaps second ridge's photovoltaic cells will receive less sunlight and so if the cells are connected in series as shown in FIG. 26C then the current produced by the whole module would be limited by the current produced by the cells in the top ridges. It is possible to conceive of a simple alternative wiring arrangement for the top cell strips so that the current will not become limited in this way and this is shown in FIG. 33. The majority of the photovoltaic cell strips 552 are made up of series connected cells as shown at FIG. 26C. However, the top two cell strips 554 shown in this FIG. 33 are made up of parallel connections of pairs of photovoltaic cells 556 that are then connected in series. Each pair produces twice the current of a single cell. The top ridges photovoltaic cells are receiving less sunlight, pairing them up like this ensures that they will produce sufficient current so as not to limit the current produced by the other photovoltaic cell strips.

Other options available for mitigating inefficiencies due to top photovoltaic cell skipping is to use higher efficiency cells for the top strips so that they can produce the same current as the other cells in the system with less available light. However, pairing up cells in groups of two or even three is a simpler way to resolve this problem.

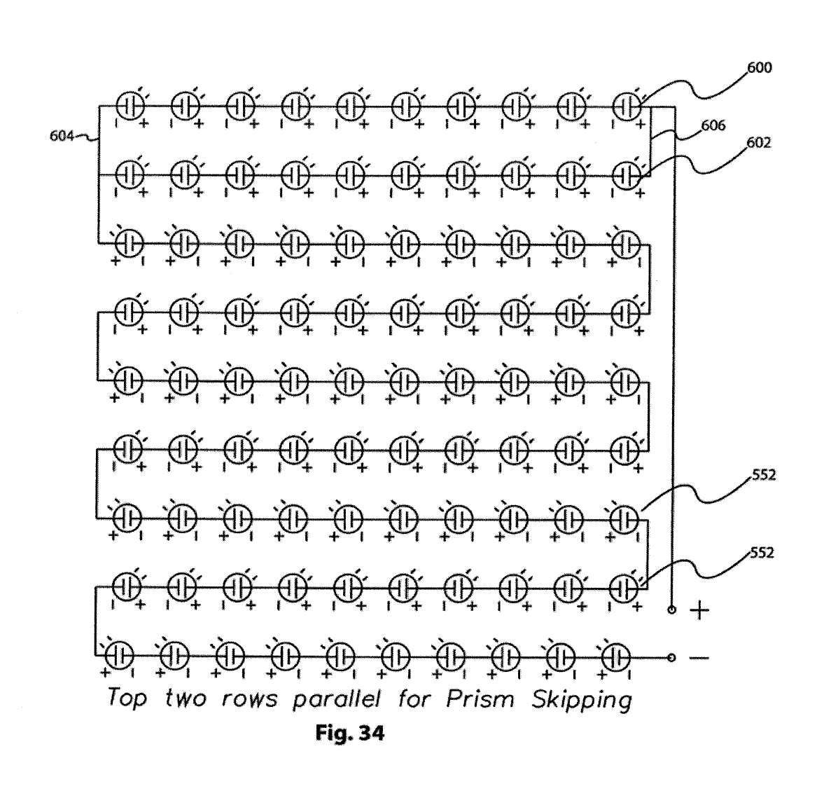

Another way to mitigating inefficiencies due to top photovoltaic cell skipping is to connect the top two strips or top three strips of PV cells in parallel. This is shown at FIG. 34. The strips of PV cells 552 are connected in the module in series. The top two strips, 600 and 602 are connected in parallel with the leads 604 and 606.

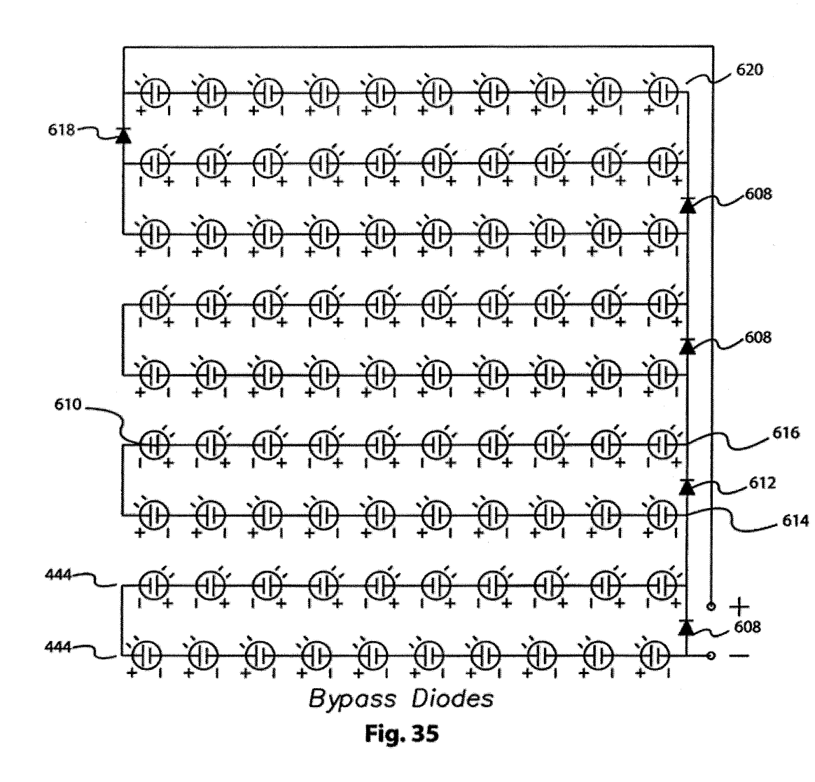

Applying by-pass diodes can protect the system from cell breakage. For example, adapting the wiring scheme from FIG. 26 and adding a bypass diode between every other pair of PV cell strips, a circuit is created whereby the breakage of any single cell does not stop the whole circuit from functioning, but instead simply stops the two strips of cells from contributing power. This is shown at FIG. 35 where the PV cell strips 444 are connected in series and diodes 608 and 614 are used to bypass pairs of PV cell strips 444. If, for example, the cell 610 were to break then the diode 612 would allow passage of current from the node 614 to the node 616 and up through the circuit. The diode 618 is positioned so as to protect against breakage in the PV cell strip 620. The use of bypass diodes in photovoltaic modules is known and the solar panel window can use the state of the art with respect to suitable by-pass diode placement and selection.

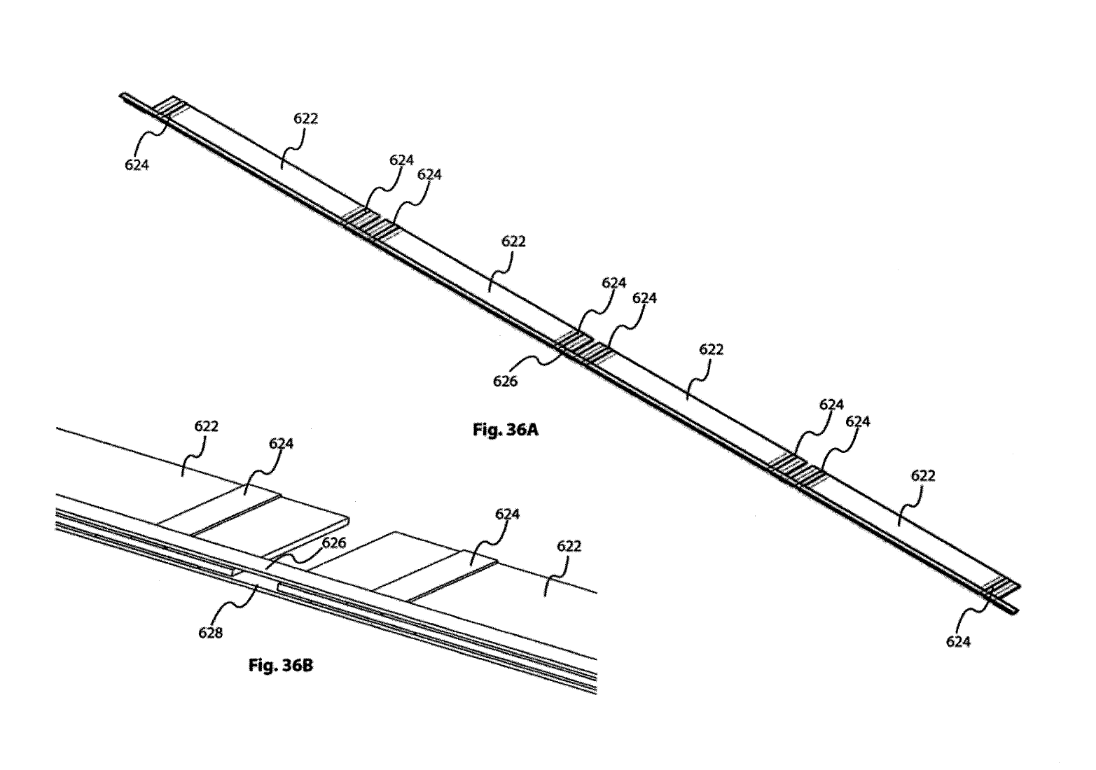

Connecting PV cells in parallel can be done as shown in FIG. 36. To connect a series of PV cells 622 in parallel, the top contacts 624 of all the cells in the strip (in this case 4) can be connected by one conductive ribbon or strip 626, and the bottom contacts (not shown) of all the cells in the strip should be connected by another conductive ribbon or strip 628.

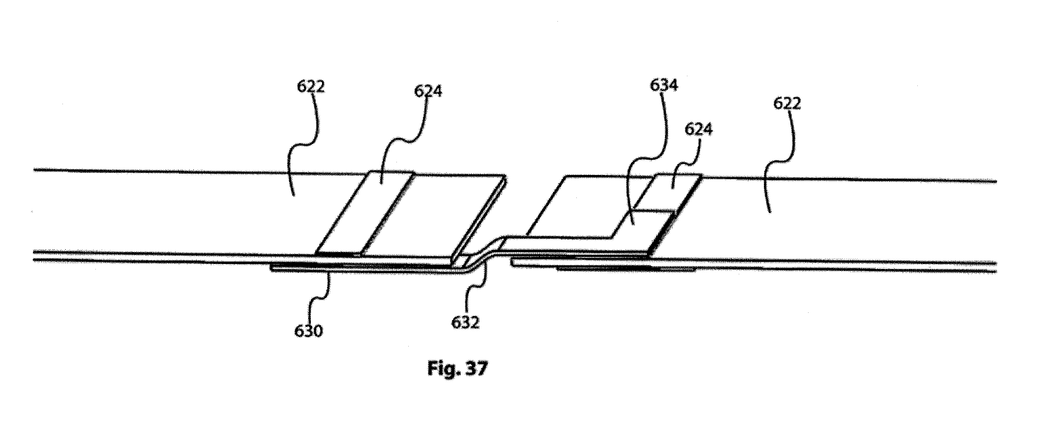

To connect PV cells in series, as is shown in FIG. 37, the bottom contact 630 of one cell 622 is connected using a solder ribbon 632 to the top contact 634 of another cell 622.

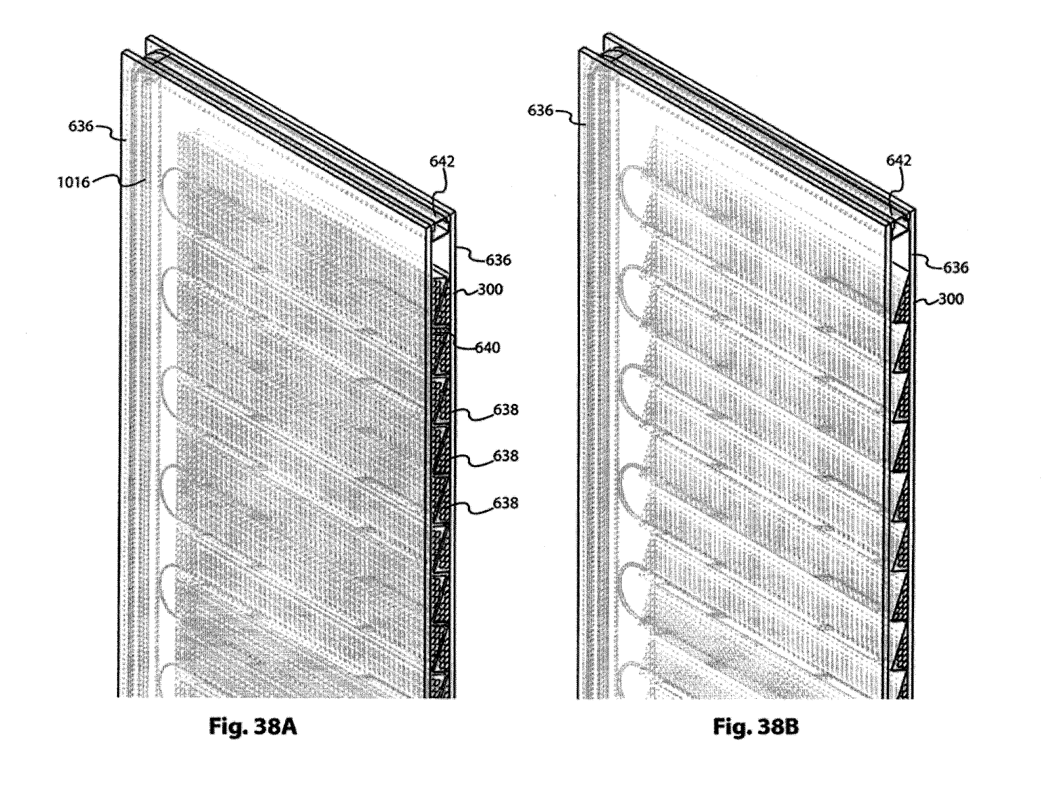

FIGS. 38A and 38B show how a sealed window unit can be made, including a spacer, using a Capture layer and a Rectifying layer. FIG. 38A shows a cut through view of a capture layer 300 and a rectifying layer 1016. Both are made of with a glass sheet 636, and with ridges 638 consisting of a matrix material such as silicone or a polymer, and glass rods 640. An aluminum spacer 642 is shown which holds the glass sheets 636 apart at a pre-determined distance. If deflection of the light as it enters the building to which it is affixed is of little consequence, a sealed window unit can be made as shown in FIG. 38B where the rectifying layer 1016 is replaced with a conventional glass sheet 636.

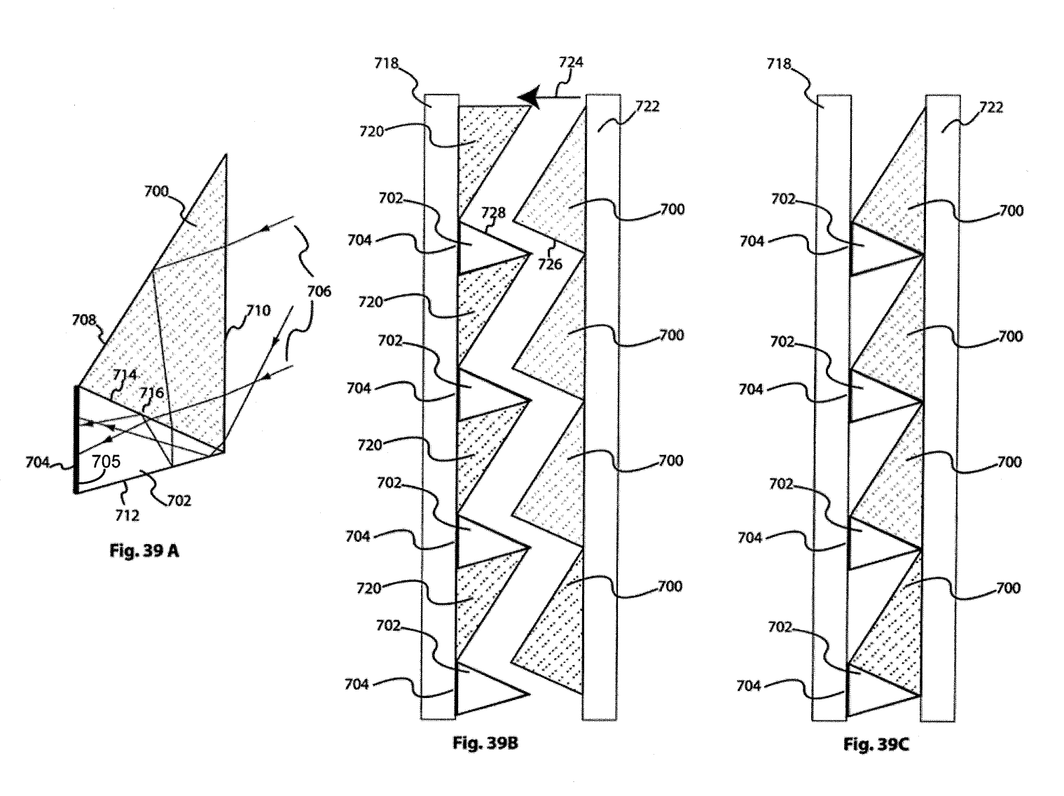

FIG. 39A shows an exemplary compound prism that can be used to capture light and guide the captured light to a PV cell, the PV cell being in optical communication with a collector face of the compound prism. The compound prism comprises a low index primary capture prism 700. The primary capture prism 700 is optically coupled to a high index secondary capture prism 702, to which a PV cell 704 is optically connected on a collector face 705. Incident light 706 on the front face 710 is captured by the capture prism 700 and reflects off the reflecting face 708. Therefrom, the light propagates to the secondary capture prism 702. At the secondary capture prism the light reflects off a reflecting face 712 and totally internally reflects off the face 714 (which can be referred to as a total internal reflection interface) of the secondary capture prism. An example of this total internal reflection is shown at 716. As will be understood by the skilled worker, the physical and optical properties of the primary and secondary capture prisms 700 and 702 can be substantially the same as those of prisms described above in relation to, for example, FIG. 30. They can be made out of the same kind of materials, they can have a mirror coating on their reflecting faces 708 and 712, either directly applied, separated by an air gap, or separated by a low index material. The prisms can be made out of composite material such as glass rods and a matrix material such as silicone or a polymer, as described above in relation to, for example, FIGS. 16A-16E. The primary capture prism 700 can be made out of very low index fluorinated PMMA (index 1.3) and the secondary capture prism 702 can be made out of high index glass (index 1.6). As will be understood by the skilled worker, any other suitable materials can be used.

To build a solar panel window using the compound prism of FIG. 39A, the PV cells 704 and the secondary capture prisms 702 can be connected to a back sheet of glass 718 (light output sheet), as shown in the example of FIG. 39B. Rectifying prisms 720 made of the same material as the primary capture prisms 700 can also be connected to the glass. The primary capture prisms 700 are connected to a second sheet of glass 722 (light input sheet). These two sheets 718 and 722 are moved towards each other as indicated by arrow 724. This results in the faces 726 of the primary capture prisms 700 abutting the face 728 of the secondary capture prism 702 such as to enable total internal reflection at the interface formed by the abutting faces 700 and 728. If deviation of the light passing through a solar panel window made using compound prisms such as shown at FIG. 39A is unimportant, then the rectifying prisms 720 can be omitted from the design to obtain a solar panel window as shown in the example of FIG. 39C.

An advantage of the solar panel window example of FIG. 39C is that PV cell strips can be positioned flat against one sheet of glass, and, if the secondary capture prism 702 is made out of glass then the PV cell strips can be encapsulated between those two sheets of glass. This mounting means may prove to be more robust. Additionally, slightly higher concentration can be achieved in this way.

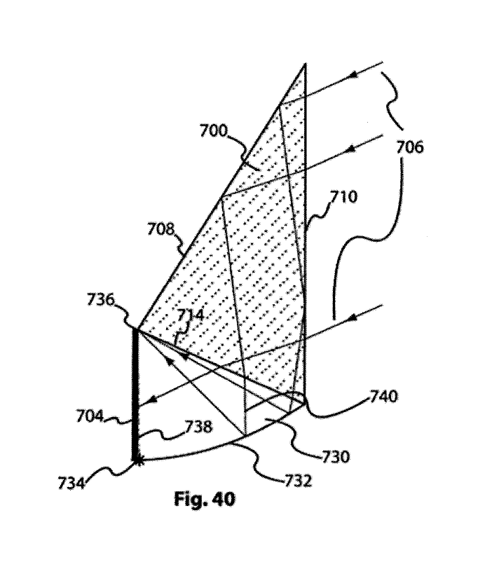

A variant of the compound prism shown at FIG. 39A is shown in FIG. 40. The difference between the compound prism of FIG. 40 and that of FIG. 39A is that the secondary capture prism 730 has a curved reflector face 732. The face 732 can be curved as a parabola whose vertex is at point 734 and whose focus is at the edge of the PV cell 736 nearest the primary capture prism. The axis of the parabola 738 is parallel to the angle of the steepest ray 740 inside the secondary capture prism. The definition of the steepest ray is a ray that is at the critical capture angle for the primary capture prism. As before the reflector face 732 of this prism can be mirror coated, or have a mirror that is conformal but separated from the face by an air gap, or a low index of refraction material can separate the mirror from the secondary capture prism. Due to the geometry is unlikely that rays will reflect multiple times off the reflector face 732 of this secondary capture prism, so the mirror can be applied directly to the prism without resulting in substantial attenuation of power.

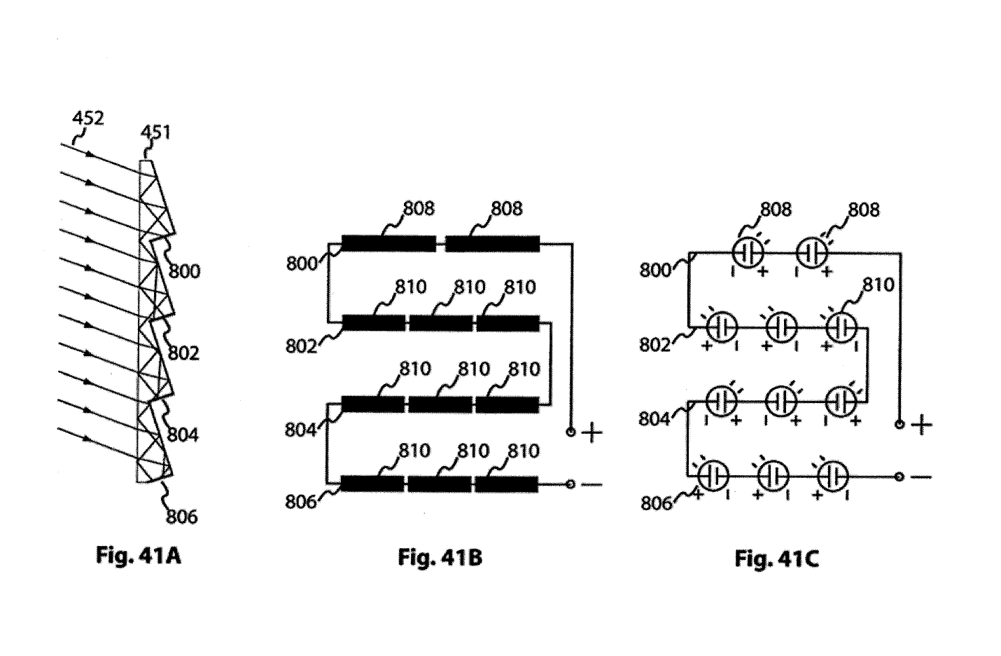

Another solution to the problem of top PV cell skipping, described above in reference to FIG. 32, is to increase slightly the size of the topmost PV cells relative to the other PV cells in the system. This is shown in FIG. 41. The topmost PV cell strip 800 is receiving two-thirds the light of each other PV cell strip (802, 804, 806). The PV cells 808 from the top most PV cell strip 800 are 50% larger so that the top PV cells 808 produce the same amount of current as the other PV cells 810 in the system in-spite of the fact that they are receiving less light. With all the PV cells matched in terms of current production in this way, the power production for the system is optimized.

In the preceding description, for purposes of explanation, numerous details are set forth in order to provide a thorough understanding of the embodiments of the invention. However, it will be apparent to one skilled in the art that these specific details are not required in order to practice the invention. In other instances, well-known electrical structures and circuits are shown in block diagram form in order not to obscure the invention.

The above-described embodiments of the invention are intended to be examples only. Alterations, modifications and variations can be effected to the particular embodiments by those of skill in the art without departing from the scope of the invention, which is defined solely by the claims appended hereto.

What is claimed is:

1. An apparatus for collecting light, the apparatus comprising:
a light-capturing pane made of a first optically transmissive material having a first refractive index, the light-capturing pane having a planar input surface and an opposite, ridged output surface, the planar input surface being in contact with an exterior medium having an exterior medium refractive index, the ridged output surface including a plurality of pairs of adjoining surfaces, each pair of adjoining surfaces defining a ridge, each pair of adjoining surfaces having a reflective surface and a collector surface, the reflective surface being in contact with a second optically transmissive material having a second refractive index lower than the first refractive index; and
a plurality of light-collecting devices in optical communication with respective collector surfaces, the apparatus having a first critical capture angle defined in accordance with at least an orientation of the reflective surfaces with respect to the planar input surface, the exterior medium refractive index, the first refractive index and the second refractive index, a portion of light incident on the input surface at an angle of incidence at least as large as the first critical capture angle being directed to one of the reflective surfaces to undergo a first total internal reflection and, therefrom, to propagate, within the light-capturing pane, to one of the collector surfaces for harvesting by a respective light-collecting device.

2. The apparatus of claim 1 further comprising:
a reflecting structure spaced-apart from the light-capturing pane, the reflecting structure facing the ridged output surface, the reflector structure and the ridged output surface defining a volume therebetween, the volume being filled substantially by the second optically transmissive material, the reflector structure having a shape complementary to the ridged output surface of the light-capturing pane, the apparatus having a second critical capture angle, a portion of light incident at an angle comprised between the second critical capture angle and the first critical capture angle being directed toward a reflective surface, transmitting through the reflective surface and through the second optically transmissive material to reflect off a segment of the reflecting structure, the segment being substantially parallel to the reflective surface, and, therefrom, to propagate through the second optically transmissive material, transmit through the reflective surface and propagate within the first optically transmissive material towards a light-collecting device.

3. The apparatus of claim 2 wherein the reflecting structure includes one of a metallic reflector, a dielectric reflector, and a reflective hologram.

4. The apparatus of claim 2 further comprising a transmissive hologram to receive light incident thereon at a first angle and to transmit the light towards the input surface at a second angle.

5. The apparatus of claim 1 further comprising a light-rectifying pane made of a third optically transmissive material having a third refractive index, the light-rectifying layer having a ridged input surface complementary to the ridged output surface of the light-capturing pane, the light-rectifying pane further having a planar output surface opposite the ridged input surface, the light-rectifying pane being spaced apart from the light-capturing pane with the output ridged surface facing the input ridged surface, light being incident on the light-capturing pane at an angle of incidence less that the first critical capture angle being transmitted through the light-capturing pane, into the light-rectifying pane and exiting the light-rectifying pane through the planar output surface of the light-rectifying layer.

6. The apparatus of claim 5 wherein the third refractive index is substantially equal to the first refractive index.

7. The apparatus of claim 5 wherein each reflective surface of the light-capturing pane has a counterpart surface in the light-rectifying pane, each reflective surface being substantially parallel to its counterpart surface.

8. The apparatus of claim 1 wherein each collector surface is substantially orthogonal to the planar input surface of the light-capturing pane.

9. The apparatus of claim 1 further comprising:
a layer of optically transmissive material having a third refractive index, the layer being formed between the input surface and the ridged output surface, the third refractive index being lower that that the first refractive index.

10. The apparatus of claim 1 wherein the light-capturing pane includes an optically transmissive sheet and a plurality of prisms secured to the optically transmissive sheet.

11. The apparatus of claim 10 wherein the prisms include a matrix and a plurality of aggregates disposed in the matrix.

12. The apparatus of claim 11 wherein the aggregates include at least one of cylinder-shaped aggregates, parallepiped-shaped aggregates, sphere-shaped aggregates, wedge-shaped aggregates, and random-shaped aggregates.

13. The apparatus of claim 1 wherein the light-collecting devices are photovoltaic cells.

14. The apparatus of claim 2 wherein the light-collecting devices are photovoltaic cells.

15. The apparatus of claim 1 wherein the first optically transmissive material includes at least one of glass, poly(methyl methacrylate), polycarbonate, urethane, poly-Urethane, silicone rubber, optical epoxies, and cyanoacrylates.

16. A solar panel window comprising a first pane and a second pane adjacent to each other, the first pane having a first ridged surface and the second pane having a second ridged surface, the first and second ridged surfaces being shaped complementary to each other, the first and second panes being secured to each other with the first ridged surface facing the second ridged surface, the solar panel window further comprising a plurality of solar cells mounted on the first ridged surface.

17. The solar panel window as claimed in claim 1 wherein the first ridged surface includes a plurality of prismatic ridges, each ridge having a long side and a short side, the plurality of solar cell being mounted to the short sides.

18. A solar panel window comprising:
an light input sheet;
an light output sheet;
a plurality of compound light capture prisms formed between the light input sheet and the light output sheet, each compound light capture prism including a first capture prism having a first refractive index and a second capture prism having a second refractive index, the second refractive index being greater than the first refractive index, the first capture prism and the second capture prism abutting each other to define a total internal reflection interface, the second capture prism having a collector face, the first capture prism to receive light from the light input sheet and to propagate the light to the second capture prism, through the total internal reflection interface, the second capture prism to propagate the light received from the first capture prism to the collector face; and
a plurality of photovoltaic cells in optical communication with respective collector faces, each photovoltaic cell to generate a voltage in accordance with the light received at its respective collector face.
